(19) United States
(12) Patent Application Publication
(10) Pub. No.: US 2016/0372382 A1
(43) Pub. Date: Dec. 22, 2016

(54) SEMICONDUCTOR DEVICE AND METHOD OF FABRICATING THE SAME

(71) Applicant: Samsung Electronics Co., Ltd., Suwon-si (KR)

(72) Inventors: HUYONG LEE, Seoul (KR); Wandon KIM, Yongin-si (KR); Jaeyeol SONG, Seoul (KR); Sangjin HYUN, Suwon-si (KR)

(73) Assignee: Samsung Electronics Co., Ltd., Suwon-si (KR)

(21) Appl. No.: 15/158,885

(22) Filed: May 19, 2016

(30) Foreign Application Priority Data
Jun. 16, 2015 (KR) 10-2015-0085210

(51) Int. Cl. H01L 21/8238; H01L 29/16; H01L 29/161; H01L 29/66; H01L 29/78; H01L 29/49; H01L 27/092; H01L 29/08; H01L 29/165

(52) U.S. Cl. CPC H01L 21/823842; H01L 29/0847; H01L 29/1608; H01L 29/161; H01L 29/165; H01L 29/7848; H01L 29/4966; H01L 27/0924; H01L 21/823821; H01L 21/823814; H01L 29/66636; H01L 29/66545

(57) ABSTRACT

A semiconductor device includes a gate structure crossing an active pattern of a substrate. The semiconductor device may include a gate dielectric pattern between the substrate and the gate electrode. The gate structure includes a gate electrode, a capping pattern on the gate electrode, and one or more low-k dielectric layers at least partially covering one or more sidewalls of the capping pattern. The gate structure may include spacers at opposite sidewalk of the gate electrode and separate low-k dielectric layers between the capping pattern and the spacers. The capping pattern may have a width that is smaller than a width of the gate electrode. The capping pattern has a first dielectric constant, and the one or more low-k dielectric layers have a second dielectric constant. The second dielectric constant is smaller than the first dielectric constant. The second dielectric constant may he greater than or equal to 1.

### CROSS-REFERENCE TO RELATED APPLICATIONS

This U.S. non-provisional patent application claims priority under 35 U.S.C. §119 to Korean Patent Application No. 10-2015-0085210, filed on Jun. 16, 2015, in the Korean Intellectual Property Office, the entire contents of which are hereby incorporated by reference.

### BACKGROUND

Example embodiments of the inventive concepts relate to a semiconductor device and/or a method of fabricating the same, and in particular, to a semiconductor device with field effect transistors and/or a method of fabricating the same.

Due to their small-size and multifunctional and/or low-cost characteristics, semiconductor devices are widely used as important elements in the electronic industry. Semiconductor devices may be classified as at least one of a memory device for storing data, a logic device for processing data, and a hybrid device including both memory elements and logic elements. In sonic cases, to enable electronic devices with fast speed and/or low power consumption, complexity and/or integration density of semiconductor devices are being increased to provide semiconductor devices having high reliability, high performance, and/or multiple functions.

### SUMMARY

Example embodiments of the inventive concepts provide a semiconductor device, in which field effect transistors with improved electric characteristics are provided.

Some example embodiments of the inventive concepts provide a method of fabricating a semiconductor device, in which field effect transistors with improved electric characteristics are provided.

According to some example embodiments of the inventive concepts, a semiconductor device may include a substrate including an active pattern and a gate structure crossing the active pattern. The gate structure may include a gate electrode, a capping pattern on the gate electrode, spacers extending in parallel with opposite sidewalls of the gate electrode, and low-k dielectric layers between the capping pattern and the spacers. The capping pattern may have a first dielectric constant, and the low-k dielectric layers may have a second dielectric constant. A bottom surface of each of the low-k dielectric layers may be positioned at a higher level than a bottom surface of the gate electrode, and the second dielectric constant may be greater than or equal to 1 and may be smaller than the first dielectric constant.

In some example embodiments, the semiconductor device may further include an interlayered insulating layer covering the gate structure. Each of the low-k dielectric layers may be enclosed by the interlayered insulating layer, a separate spacer of the spacers, the capping pattern, and the gate electrode.

In some example embodiments, each of the low-k dielectric layers may be in direct contact with the capping pattern a separate spacer of the spacers.

In some example embodiments, the capping pattern, the spacers, and the low-k dielectric layers may have coplanar top surfaces.

In some example embodiments, the gate structure may further include a gate dielectric pattern between the substrate and the gate electrode, the gate dielectric pattern may include a first extended portion extending in a direction perpendicular to a top surface of the substrate, and the gate electrode may cover a top surface of the first extended portion.

In some example embodiments, the gate structure may further include a barrier pattern between the substrate and the gate electrode, the barrier pattern may include a second extended portion extending in a direction perpendicular to a top surface of the substrate, and the gate electrode may cover a top surface of the second extended portion.

In some example embodiments, the barrier pattern may include first and second barrier layers sequentially stacked on the substrate, and the first and second barrier layers may include different materials.

In some example embodiments, a width of an upper portion of the gate electrode may be greater than that of a lower portion of the gate electrode.

In some example embodiments, the gate electrode may include a first work-function metal pattern and an electrode pattern an upper portion of the first work-function metal pattern, and a width of the electrode pattern may be smaller than the width of the upper portion of the first work-function metal pattern

In some example embodiments, the low-k dielectric layers may cover opposite sidewalls of the electrode pattern and a portion of a top surface of the first work-function metal pattern.

In some example embodiments, the width of the electrode pattern may be substantially equal to a width of the capping pattern.

In some example embodiments, the gate electrode may include a first work-function metal pattern and an electrode pattern on the first work-function metal pattern, and a width of the electrode pattern may be greater than that of the capping pattern.

In some example embodiments, the electrode pattern a have a to surface at a higher level than a bottom surface of the capping pattern.

In some example embodiments, the gate electrode may include a first work-function metal pattern, a second work-function metal pattern, and an electrode pattern on the first and second work-function metal patterns, and a top surface of the first work-function metal pattern may be coplanar with a top surface of the second work-function metal pattern.

In some example embodiments, the first work-function metal patter may have a first resistance, the second work-function metal pattern may have a second resistance, and the electrode pattern may have a third resistance. The second resistance may be smaller than the first resistance and greater than the third resistance.

In some example embodiments, the low-k dielectric layer may include at least one of a gaseous material and a silicon oxide material.

In some example embodiments, the semiconductor device may further include device isolation layers provided in the substrate to define the active pattern. The active pattern may include an upper portion protruding between the device isolation layers.

According to some example embodiments of the inventive concepts, semiconductor device may include a substrate including an active pattern and agate structure crossing the active pattern. The gate structure may include a gate electrode, a capping pattern on the gate electrode, and a low-k dielectric layer covering both sidewalls of the capping pattern. A width of the capping pattern may be smaller than a width of the gate electrode, and the low-k dielectric layer may have a dielectric constant ranging from 1 to 4. The width of the gate electrode may be a first width of the gate electrode, and the width of the capping pattern may be a second width of the capping pattern. The first width of the gate electrode may be a maximum width of the gate electrode.

In some example embodiments, the gate electrode may include a work-function metal pattern and an electrode pattern on the work-function metal pattern, and a width of an upper portion of the work-function metal pattern may be greater than a width of a lower portion of the work-function metal pattern.

In some example embodiments, the low-k dielectric layer may cover both sidewalls of the electrode pattern.

In some example embodiments, a top surface of the electrode pattern may be positioned at a higher level than a bottom surface of the capping pattern.

According to some example embodiments of the inventive concepts, a semiconductor device may include a substrate, device isolation layers in the substrate to define an active pattern and a gate structure crossing the active pattern. The gate structure may include a gate electrode and a gate dielectric pattern between the substrate and the gate electrode. The gate dielectric pattern may include a first extended portion extending in a direction perpendicular to a top surface of the substrate, and the gate electrode may cover a top surface of the first extended portion.

In some example embodiments, the gate structure may further include a barrier pattern between the gate dielectric pattern and the gate electrode. The barrier pattern may include a second extended portion extending in the direction perpendicular to the top surface of the substrate, and the gate structure may be provided to cover a top surface of the second extended portion.

According to some example embodiments of the inventive concepts, a method of fabricating a semiconductor device may include forming device isolation layers in a substrate to define an active pattern, forming a sacrificial gate pattern crossing the active pattern and a set of spacers covering opposite sidewalls of the sacrificial gate pattern, removing the sacrificial gate pattern to form a gate trench defined by spacers, forming a gate electrode and a capping pattern sequentially filling the gate trench, and recessing an upper portion of the gate electrode using the capping pattern as an etch mask to form a set of recess regions exposing opposite sidewalk of the capping pattern.

In some example embodiments, the capping pattern may have a first dielectric constant, and the recess regions may each be filled with a low-k dielectric layer having a second dielectric constant. The second dielectric constant may be greater than or equal to 1 and may be smaller than the first dielectric constant.

In some example embodiments, the low-k dielectric layers may include a gaseous material.

In some example embodiments, the method may further include forming an interlayered insulating layer covering the capping pattern. The interlayered insulating layer may include silicon dioxide. The interlayered insulating layer may at least partially fill the recess regions such that the low-k dielectric layers include silicon dioxide.

In some example embodiments, before the forming of the gate electrode, the method may further include forming a gate dielectric layer to partially fill the gate trench, a portion of the gate dielectric layer covering the spacers, and partially removing the gate dielectric layer covering the spacers to form a gate dielectric pattern.

In some example embodiments, the forming of the gate electrode may include forming a work function metal layer, recessing an upper portion of the work-function metal layer to form a work-function metal pattern, and forming an electrode pattern covering a top surface of the work-function metal pattern.

In some example embodiments, a semiconductor device includes a substrate including an active pattern; and a gate structure crossing the active pattern. The gate structure may include a gate electrode, a capping pattern on the gate electrode, the capping pattern having a first dielectric constant, and a low-k dielectric layer at least partially covering a sidewall of the capping pattern, the low-k dielectric layer having a second dielectric constant, the second dielectric constant being smaller than the first dielectric constant.

In some example embodiments, the gate electrode includes an extended portion, the extended portion covering a lower portion of the sidewall of the capping pattern.

In some example embodiments, the low-k dielectric layer includes a first portion and a second portion, the first and second portions including different materials.

In some example embodiments, the first portion covers an upper portion of the sidewall, and the second portion covers a lower portion of the sidewall.

In some example embodiments, the semiconductor device includes an interlayered insulating layer covering the gate structure, wherein the first portion of the low-k dielectric layer is an extended portion of the interlayered insulating layer.

### BRIEF DESCRIPTION OF THE DRAWINGS

Example embodiments will he more clearly understood from the following brief description taken in conjunction with the accompanying drawings. The accompanying drawings represent non-limiting, example embodiments as described herein.

FIG. 1 is a plan view schematically illustrating a semiconductor device according to some example embodiments of the inventive concepts.

FIG. 2 is a plan view illustrating a portion of a semiconductor device according to some example embodiments of the inventive concepts.

FIG. 3A is a sectional view taken along lines I-I′ and II-II′ of FIG. 2.

FIG. 3B is a sectional view taken along line III-III′ of FIG. 2.

FIG. 4A, FIG. 4B, FIG. 4C, and FIG. 4D are enlarged sectional views illustrating gate structures (e.g., of the portion M of FIG. 3B), according to some example embodiments of the inventive concepts,

FIG. 5A, FIG. 5B, FIG. 6A, FIG. 6B, FIG. 7A, FIG. 7B, FIG. 8A, FIG. 8B, FIG. 9A, FIG. 9B, FIG. 10A, FIG. 10B, FIG. 11A, FIG. 11B, FIG. 12A, FIG. 12B, FIG. 13A, FIG. 13B, FIG. 14A, and FIG. 14B are sectional views illustrating a method of fabricating a semiconductor device, according to some example embodiments of the inventive concepts.

FIG. 15 is a block diagram illustrating an example of an electronic system including a semiconductor device according to some example embodiments of the inventive concepts.

FIG. 16 is a block diagram illustrating an example of an electronic device including a semiconductor device according to some example embodiments of the inventive concepts.

FIG. 17 is an equivalent circuit diagram illustrating an SRAM cell according to some example embodiments of the inventive concepts.

FIG. 18, FIG. 19, and FIG. 20 are diagrams illustrating some examples of a multimedia device including a semiconductor device according to some example embodiments of the inventive concepts.

It should be noted that these figures are intended to illustrate the general characteristics of methods, structure and/or materials utilized in some example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Some example embodiments of the inventive concepts will now be described more fully with reference to the accompanying drawings, in which some example embodiments are shown. Some example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and the are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

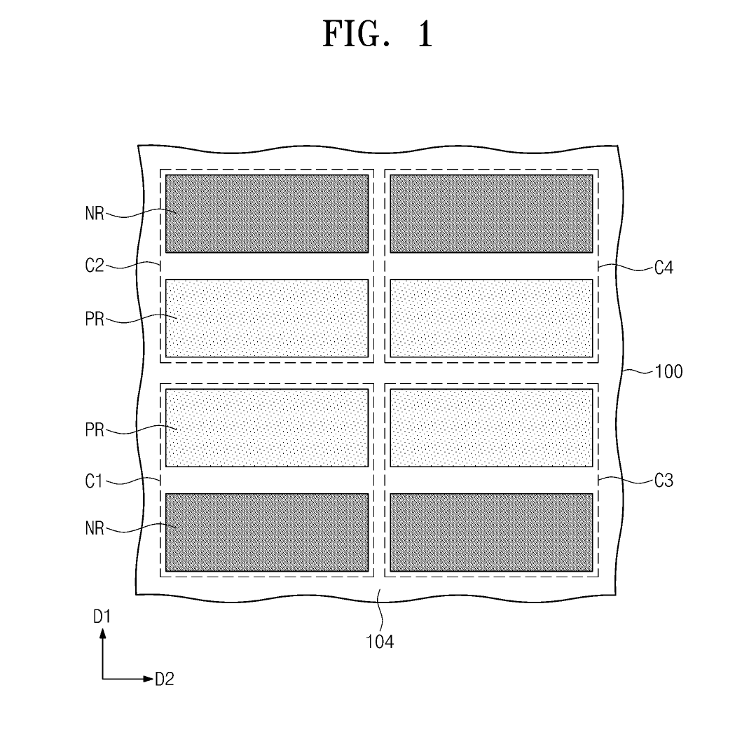

FIG. 1 is a plan view schematically illustrating a semiconductor device according to some example embodiments of the inventive concepts.

Referring to FIG. 1, a semiconductor device according to some example embodiments of the inventive concepts may include a plurality of logic cells C1, C2, C3, and C4 provided on a substrate 100. Each of the logic cells C1, C2, C3, and C4 may include a plurality of transistors. As an example, the semiconductor device may include a first logic cell C1, a second logic cell C2 spaced apart from the first logic cell C1 in a first direction D1, a third logic cell C3 spaced apart from the first logic cell C1 in a second direction D2 crossing the first direction D1, and a fourth logic cell C4 spaced apart from the second logic cell C2 in the second direction D2. Each of the logic cells C1, C2, C3, and C4 may include active regions spaced apart from each other by device isolation lavers 104. Each of the logic cells C1, C2, C3, and C4 may include a PMOSFET region PR and an NMOSFET region NR which are spaced apart from each other by the device isolation layers 104.

As an example, the PMOSFET and NMOSFET regions PR and NR may be spaced apart from each other in the first direction D1. The PMOSFET region PR of the first logic cell C1 may be disposed adjacent to the PMOSFET region PR of the second logic cell C2 in the first direction D1. In the following description, a term “logic cell” may refer to a unit circuit configured to perform a single logical operation. Further, the number of the logic cells may be variously changed from that illustrated in the drawing.

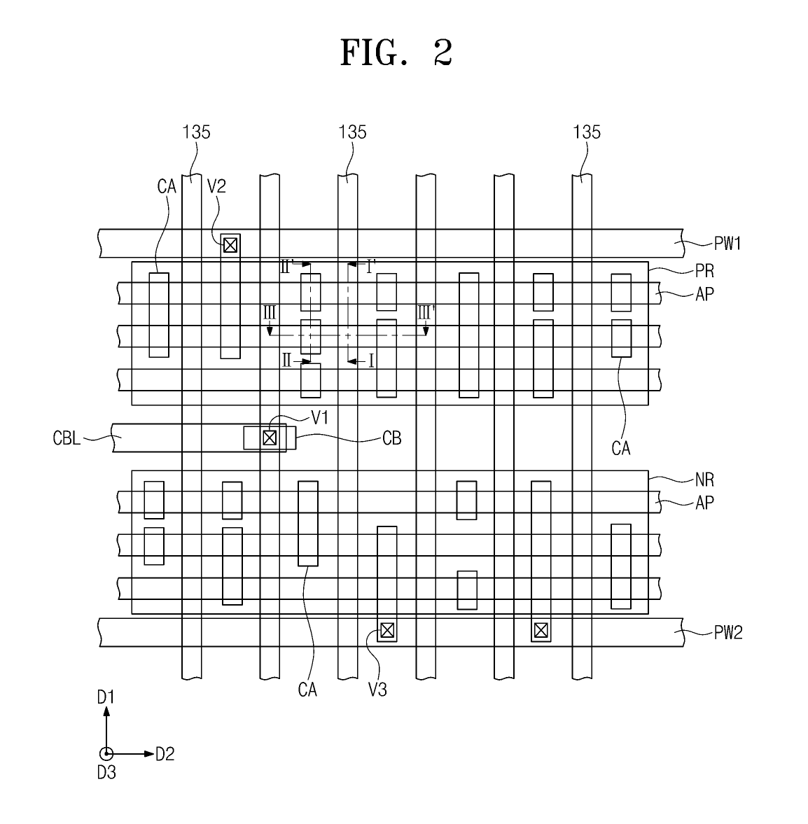

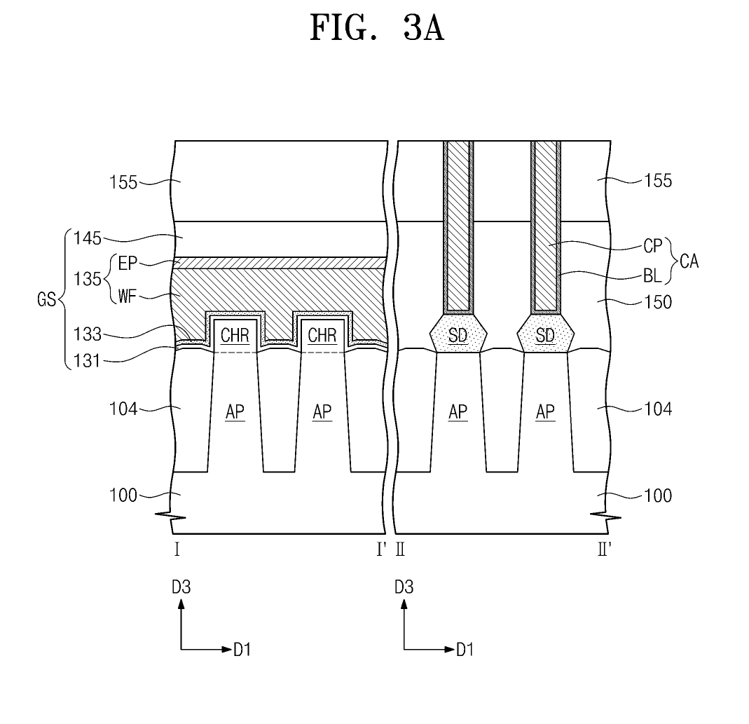

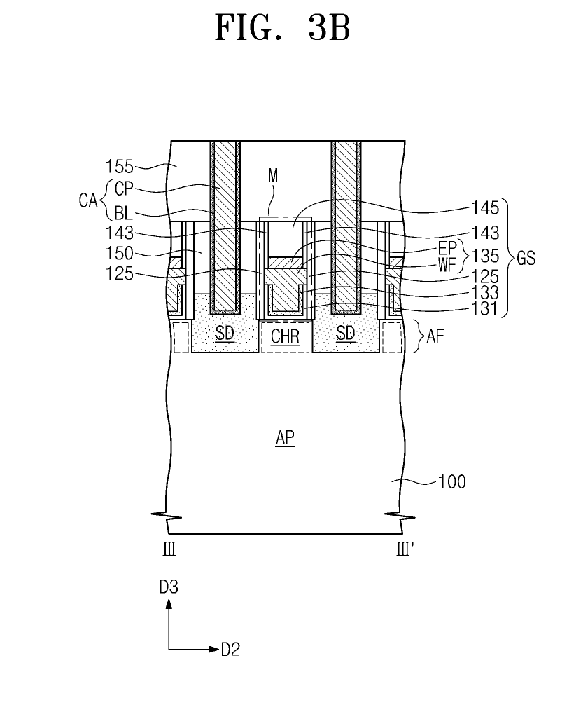

FIG. 2 is a plan view illustrating a portion of a semiconductor device according to some example embodiments of the inventive concepts. For example, FIG. 2 is a plan view illustrating the first logic cell C1 of FIG. 1. Hereinafter, various example embodiments of the inventive concepts will be described with reference to the first logic cell C1 of FIG. 1, but some logic cells may have substantially the same or similar structure as that of the first logic cell C1. FIG. 3A is a sectional view taken along lines I-I′ and II-II′ of FIG. 2. FIG. 3B is a sectional view taken along line of FIG. 2.

Referring to FIG. 2, FIG. 3A, and FIG. 3B, device isolation layers 104 may be provided in the substrate 100 to define the PMOSFET and NMOSFET regions PR and NR. The device isolation layers 104 may be formed in a top portion of the substrate 100. In some example embodiments, the device isolation layers 104 may include an insulating material, such as silicon oxide.

The PMOSFET and NMOSFET regions PR and NR may be spaced apart from each other, in the first direction D1 parallel to a top surface of the substrate 100, by the device isolation layers 104 interposed therebetween. Although each of the PMOSFET and NMOSFET regions PR and NR is illustrated to be a single region, it may include a plurality of regions spaced apart from each other by the device isolation layers 104.

A plurality of active patterns AP may be provided on the PMOSFET and NMOSFET regions PR and NR to extend in the second direction D2 crossing the first direction D1. The active patterns AP may be arranged along the first direction D1. The active patterns AP may have a first conductivity type. The device isolation layers 104 may be provided at both sides of each of the active patterns AP to define the active patterns AP. Although the number of the active patterns AP provided on each of the PMOSFET and NMOSFET regions PR and NR is shown to be three, example embodiments of the inventive concepts may not be limited thereto.

Each of the active patterns AP may include active fins AF protruding between the device isolation layers 104. For example, each of the active fins AF may have a structure protruding from the active pattern AP in a third direction D3 perpendicular to the top surface of the substrate 100. Each of the active fins AF may include source/drains SD and a channel region CHR interposed between the source/drains SD.

In some example embodiments, gate structures GS may be provided on the substrate 100 to cross the active patterns AP. The gate structures GS may be overlapped with the channel regions CHR of the active fins AF, respectively, when viewed in plan view. In other words, the gate structures GS may be provided to cross the active fins AF and extend parallel to the first direction D1 and may be a line-shaped structure. Each of the gate structures GS may include gate spacers 125, a gate dielectric pattern 131, a barrier pattern 133, a gate electrode 135, a capping pattern 145, and one or more low-k dielectric layers 143 between the capping pattern 145 and the separate gate spacers 125. The gate structures GS will be described in further detail below.

The source/drains SD may be provided on or in the active fins AF and at both sides of each of the gate structures GS. The source/drains SD may be epitaxial patterns, which are epitaxially grown from the active patterns AP. In some example embodiments, when viewed in a vertical section, top surfaces of the channel regions CHR may be positioned at a higher level than bottom surfaces of the source/drains SD. In some example embodiments, top surfaces of the source/drains SD may be positioned at the same level as, or a higher level than, the top surfaces of the channel regions CHR.

The source/drains SD may include a semiconductor element different from those of the substrate 100. For example, the source/drains SD may be formed of or include a semiconductor material having a lattice constant different from (for example, greater or smaller than) the substrate 100. Thus, compressive stress or a tensile stress may be exerted to the channel regions CHR. In some example embodiments, the substrate 100 is a silicon wafer and the source/drains SD may be formed of or include a silicon-germanium (e.g., e-SiGe) or germanium layer. In this case, the source/drains SD may exert a compressive stress on the channel regions CHR (preferably, of PMOS field effect transistors). In some example embodiments, the substrate 100 is a silicon wafer and the source/drains SD may be formed of or include a silicon carbide (SiC) layer. In this case, the source/drains SD may exert a tensile stress on the channel regions CHR (preferably, of NMOS field effect transistors). The compressive or tensile stress to be exerted on the channel regions CHR by the source/drains SD may enable increased mobility of carriers in the channel regions CHR when the field effect transistors are operated. The source/drains SD may have a second conductivity type that is different from that of the active pattern AP.

A first interlayered insulating layer 150 may be provided on the substrate 100. The first interlayered insulating layer 150 may be provided to cover the source/drains SD and sidewalls of the gate structures GS. The first interlayered insulating layer 150 may have a top surface that is substantially coplanar with those of the gate structures GS. A second interlayered insulating layer 155 may be formed on the first interlayered insulating layer 150 to cover the gate structures GS.

In addition, contacts CA may be provided at both sides of each of the gate electrodes 135 and may be electrically connected to the source/drains SD through the first and second interlayered insulating layers 150 and 155. Each of the contacts CA may be connected to a corresponding one or ones of the source/drains SD, but example embodiments of the inventive concepts may not be limited thereto. Each of the contacts CA may include a conductive pillar CP and a contact barrier layer BL enclosing the conductive pillar CP. The contact barrier layer BL may be provided to cover side and bottom surfaces of the conductive pillar CP. The conductive pillar CP may be formed of or include a metallic material (e.g., tungsten), The contact barrier layer BL may be formed of or include at least one of metal nitrides (e.g., Ti/TiN).

Although not shown, metal silicide layers may be respectively interposed between the source/drains SD and the contacts CA. For example, the contacts CA may be electrically connected to the source/drains SD through the metal silicide layers. The metal silicide layers SC may be formed of or include at least one of metal-silicide materials (e.g., titanium silicide, tantalum silicide, or tungsten silicide).

A gate contact CB and a conductive line CBL may be provided on one of the gate electrodes 135. A first via V1 may be disposed between the gate contact CB and the conductive line CBL. The conductive line CBL may be electrically connected to the one of the gate electrodes 135 through the first via V1 and the gate contact CB to serve as a current path for applying signals to the one of the gate electrodes 135.

The first logic cell C1 may include a first wire PW1 provided near an outer edge of the PMOSFET region PR and a second wire PW2 provided near an outer edge of the NMOSFET region NR. As an example, the first wire PW1 on the PMOSFET region PR may serve as a current path for transmitting a drain voltage Vdd (e.g., a power voltage). The second wire PW2 on the NMOSFET region NR may serve as a current path for transmitting a source voltage Vss (e.g., a ground voltage).

Referring back to FIG. 1 and FIG. 2, the first and second wires PW1 and PW2 may extend parallel to the second direction D2 and may be shared by a plurality of logic cells disposed adjacent to each other in the second direction D2. As an example, the first wire PW1 may be shared by the first logic cell C1 and the third logic cell C3. Furthermore, the first wire PW1 may be shared by the PMOSFET regions PR of the first and second logic cells C1 and C2.

In some example embodiments, a second via V2 may be provided on one of the contacts CA. Accordingly, the source/drain SD connected to the one of the contacts CA may be electrically connected to the first wire PW1 through the one of the contacts CA and the second via V2. Similarly, the source/drain SD on the NMOSFET region NR may also be electrically connected to the second wire PW2 through the one of the contacts CA and a third via V3.

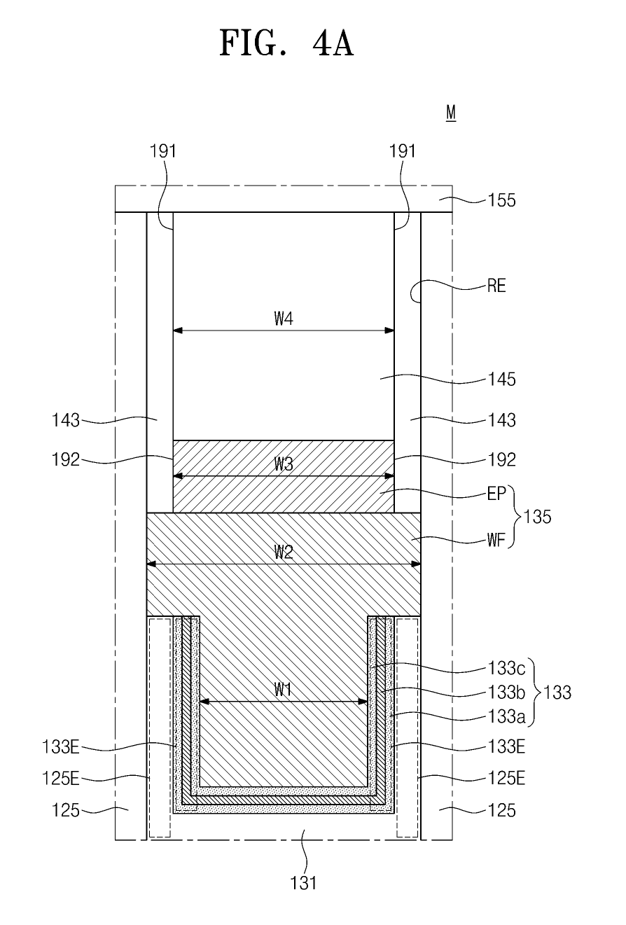

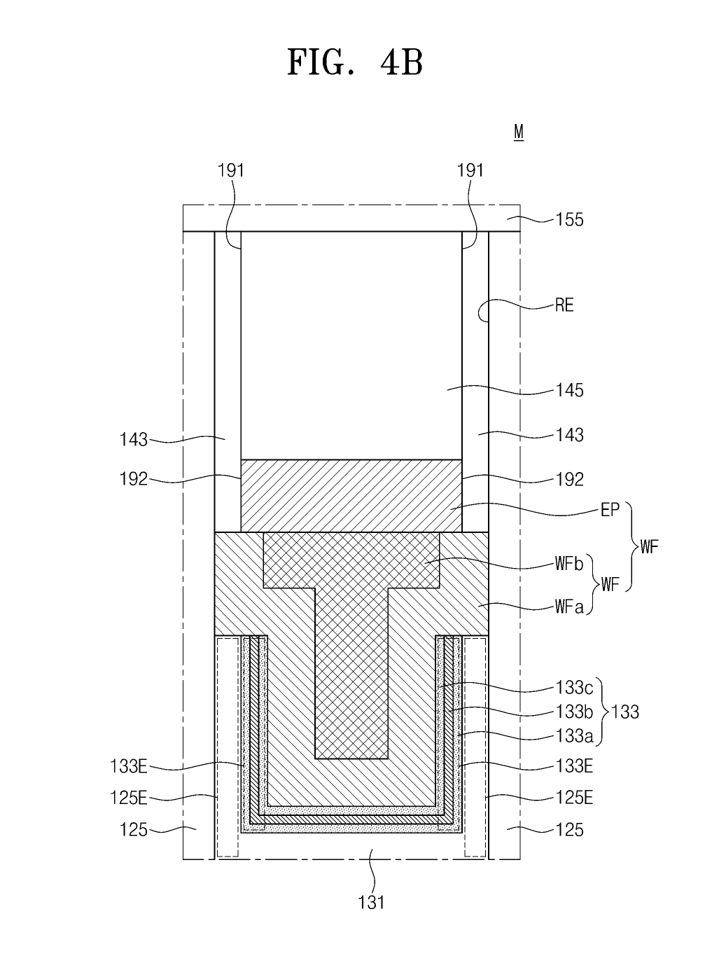

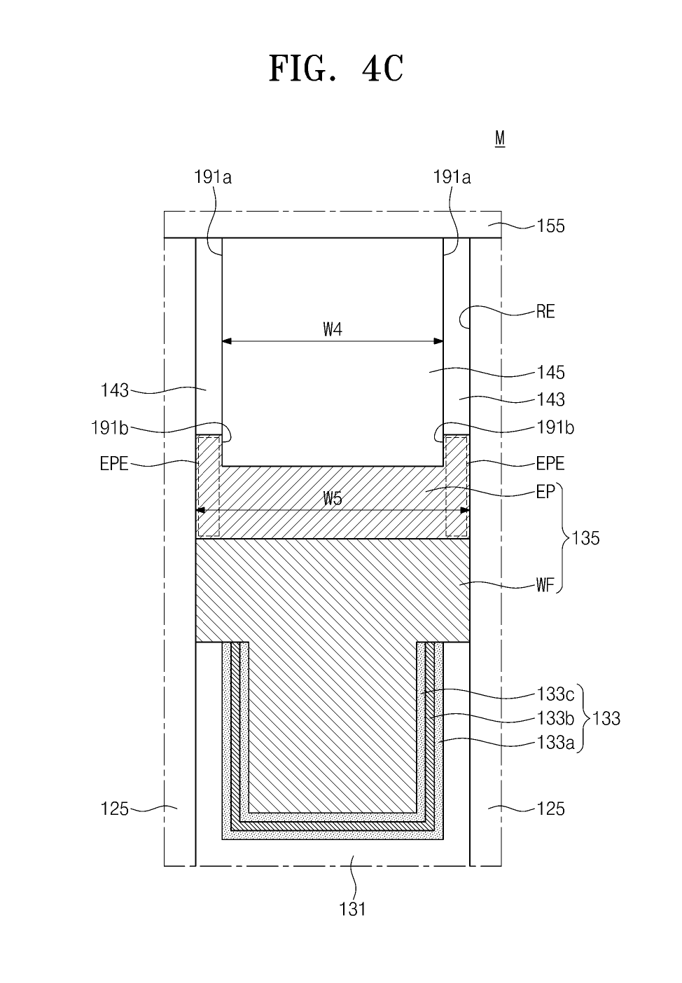

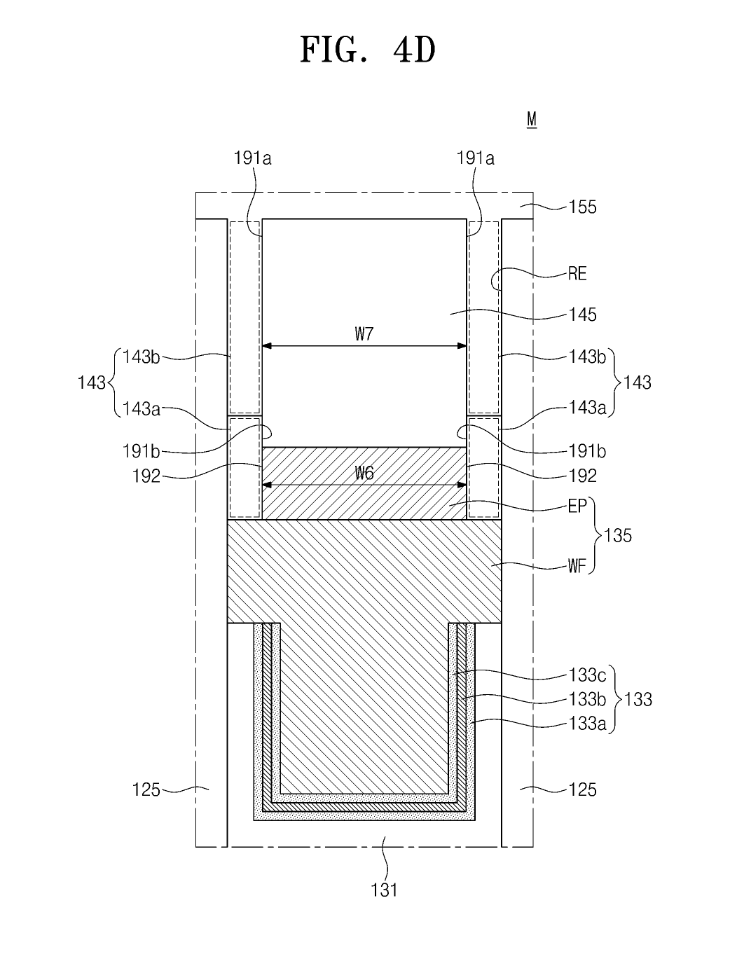

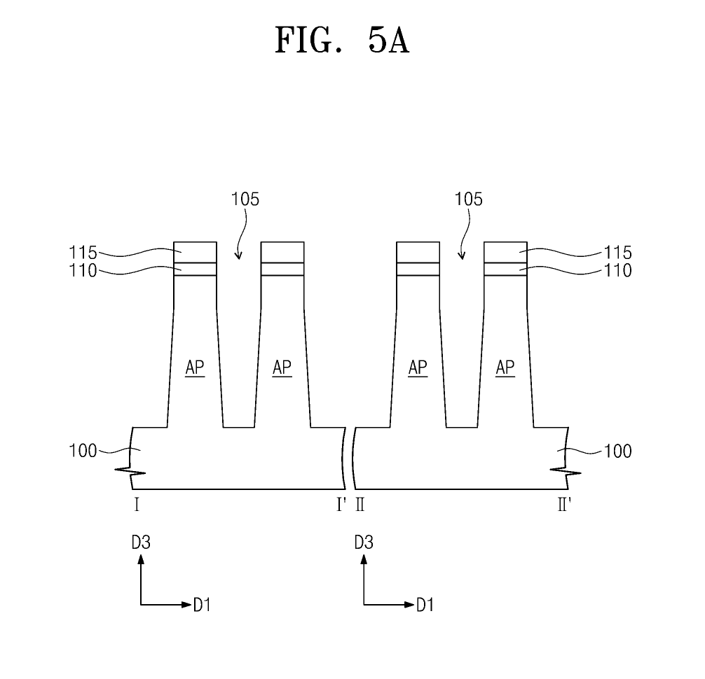

FIG. 4A, FIG. 4B, FIG. 4C, and FIG. 4D are enlarged sectional views illustrating some examples of the gate structure GS (e.g., of the portion M of FIG. 3B), according to some example embodiments of the inventive concepts. The gate structure GS according to some example embodiments of the inventive concepts will be described in more detail with reference to FIG. 4A, FIG. 4B, FIG. 4C, and FIG. 4D.

In some example embodiments, as shown in FIG. 2, FIG. 3A, FIG. 3B, and FIG. 4A, the gate electrode 135 may have a line-shaped structure crossing the active patterns AP and extending in the first direction D1. For example, the gate electrode 135 may include a work-function metal pattern WF and an electrode pattern EP on the work-function metal pattern WF.

A set of the gate spacers 125 may be provided on opposite sidewalk of the gate electrode 135. It will be understood that a set of the gate spacers 125 may include a pair of gate spacers 125 provided on opposite sidewails of the gate electrode 135. The gate spacers 125 may extend along the gate electrodes 135, in parallel with opposite sidewalk of at least the capping pattern 145, or in the first direction D1. A top surface of each of the gate spacers 125 may be positioned at a higher level than that of the gate electrode 135. Furthermore, the top surface of each of the gate spacers 125 may be coplanar with that of the first interlayered insulating layer 150. The gate spacers 125 may include at least one of SiO2, SiCN, SiCON, or SiN. Alternatively, the gate spacers 125 may have a multi-layer structure including at least one of SiO2, SiCN, SiCON, or SiN.

The gate dielectric pattern 131 may be provided between the gate electrode 135 and the substrate 100 and between the gate electrode 135 and the gate spacers 125. The gate dielectric pattern 131 may extend along a bottom surface of the gate electrode 135. For example, as shown in FIG. 3A, the gate dielectric pattern 131 may be provided to cover top and side surfaces of the channel regions CHR. The gate dielectric pattern 131 may extend horizontally from the active fins AF to partially cover top surfaces of the device isolation layers 104. in some example embodiments, the gate dielectric pattern 131 may be provided to partially expose the top surfaces of the device isolation layers 104. The exposed portions of the top surfaces of the device isolation layers 104 may he covered with the first interlayered insulating layer 150 (e.g., see the section taken along line II-II′ of FIG. 3A).

Furthermore, as shown in FIG. 4A, the gate dielectric pattern 131 may include a pair of first extended portions 125E. The first extended portions 125E may extend in the third direction D3 along inner sidewalls of the gate spacers 125. Top surfaces of the first extended portions 125E may be covered with the work-function metal pattern of the gate electrode 135, For example, the top surfaces of the first extended portions 125E may be positioned between top and bottom surfaces of the work-function metal pattern WF.

The gate dielectric pattern 131 may include a high-k dielectric material. For example, the gate dielectric pattern 131 may be formed of or include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The barrier pattern 133 may be interposed between the gate electrode 135 and the gate dielectric pattern 131. The barrier pattern 133, along with the gate dielectric pattern 131, may extend along the bottom surface of the gate electrode 135. Referring back to FIG. 4A, the barrier pattern 133 may include a pair of second extended portions 133E. The second extended portions 133E may extend in the third direction D3 along inner sidewalk of the first extended portions 125E. The second extended portions 133E may have top surfaces that are substantially coplanar with those of the first extended portions 125E. In addition, the top surfaces of the second extended portions 133E may be covered with the work-function metal pattern WF. For example, the top surfaces of the second extended portions 133E may be positioned between the top and bottom surfaces of the work-function metal pattern WF.

Furthermore, the barrier pattern 133 may include first and second barrier layers 133a and 133b sequentially stacked on the substrate 100. The first barrier layer 133a may prevent metallic elements from being diffused from the work-function metal pattern WF to the gate dielectric pattern 131. The second barrier layer 133b may protect the first barrier layer 133a and the gate dielectric pattern 131 from an etching process. In some example embodiments, the barrier pattern 133 may further include a third barrier layer 133c interposed between the second barrier layer 133b and the work-function metal pattern WF. By virtue of the third barrier layer 133c, it is possible to more effectively prevent the metallic elements contained in the work-function metal pattern WF from being diffused.

The first, second, and third barrier layers 133a, 133b, and 133c may include metal layers that are formed of the same material or different materials. As an example, the first, second, and third barrier layers 133a, 133b, and 133c may include binary metal nitrides (e.g., titanium nitride (TiN), tantalum nitride (TaN), tungsten nitride (WN), and hafnium nitride (HfN)) and/or ternary metal nitrides (e.g., titanium aluminum nitride (TiAlN), tantalum aluminum nitride (TaAlN), and hafnium aluminum nitride (HfAlN)). In some example embodiments, the first barrier layer 133a may be formed of or include a titanium nitride layer (TiN), the second barrier layer 133b may be formed of or include a tantalum nitride layer (TaN), and the third barrier layer 133c may be formed of or include a titanium nitride layer (TiN).

In some example embodiments, the barrier pattern 133 may not cover the top surfaces of the first extended portions 125E of the gate dielectric pattern 131. In other words, since the work-function metal pattern WF is in direct contact with the top surfaces of the first extended portions 125E, metallic elements in the work-function metal pattern WF may be diffused into the first extended portions 125E. However, owing to the presence of the barrier pattern 133, it is possible to prevent such metallic elements from being diffused into a portion of the gate dielectric pattern 131, which is interposed between the first extended portions 125E or is positioned on the channel region CHR. Accordingly, even when metallic elements are diffused into the first extended portions 125E, it is possible to prevent electrical and physical characteristics of the field effect transistor from being deteriorated.

The work-function metal pattern WF may include a metallic material fur controlling a work function of the channel region CHR. For example, the work-function metal pattern WF may be formed of a conductive material having a specific work function to contribute to control a threshold voltage of the field effect transistor. For example, the work-function metal pattern WF may have a work function ranging from about 4.1 eV to about 5.2 eV.

The work-function metal pattern WF may include a lower portion with a first width W1 and an upper portion with a second width W2, when measured in the second direction D2. Here, the second width W2 may be greater than the first width W1. The second width W2 may be substantially equal to a distance between a pair of the gate spacers 125. The work-function metal pattern WF may have a discontinuously-increasing width in a direction from bottom to top of the work-function metal pattern WF. The sidewall of the work-function metal pattern WF may have a staircase profile. An interface between the lower and upper portions of the work-function metal pattern WF may be positioned at substantially the same level as the top surfaces of the first and second extended portions 125E and 133E. The work-function metal pattern WF may have a substantially flat top surface.

The work-function metal pattern WF may be formed of or include at least one of metals (e.g., titanium (Ti), tantalum (Ta), hafnium (Hf), tungsten (W), molybdenum (Mo), or aluminum (Al)), nitrides containing at least one of the metals, carbides, silicon nitride, or suicides. In some example embodiments, the work-function metal pattern WF may be formed of or include platinum (pt), rubidium (Ru), iridium oxide (IrO), or rubidium oxide (RuO).

In some example embodiments, the work-function metal pattern WF on the PMOSFET region PR may contain a material different from the work-function metal pattern WF on the NMOSFET region NR. This may make it possible to make a difference between work functions of the channel regions provided on the PMOSFET and NMOSFET regions PR and NR. In some example embodiments, the work-function metal pattern WF on the PMOSFET region PR may have a double-layer structure, as will be described in more detail below.

The electrode pattern EP on the work-function metal pattern WF may have a third width W3. The third width W3 may be smaller than the second width W2. The electrode pattern EP may be formed of or include at least one low resistance metallic material, such as aluminum (Al), tungsten (W), titanium (Ti), or tantalum (Ta). in general, the work-function metal pattern WF may be formed of a material, whose resistance is much higher than that of the electrode pattern EP. Accordingly, the use of the work-function metal pattern WF may lead to an increase in resistance of the gate electrode 135 and deterioration in AC performance of the field-effect transistor. However, since the electrode pattern EP has a relatively low resistance, it is possible to reduce total resistance of the gate electrode 135 and improve AC performance of the field-effect transistor.

The capping pattern 145 may be provided on the gate electrode 135, The capping pattern 145 may extend along the gate electrode 135 or in the first direction D1. The capping pattern 145 may have a fourth width W4, which may be smaller than the second width W2 and may be substantially equal to the third width W3. A top surface of the capping pattern 145 may be positioned at the same level as those of the gate spacers 125.

The capping pattern 145 may include a material having an etch selectivity with respect to the first and second interlayered insulating layers 150 and 155. For example, the capping pattern 145 may include at least one of SiON, SiCN, SiCON, and SiN. Furthermore, the capping pattern 145 may have a first dielectric constant.

Recess regions RE may be defined between the capping pattern 145 and the gate spacers 125. For example, each of the recess regions RE may be an empty region delimited or surrounded by the work-function metal pattern WF, the electrode pattern EP, the capping pattern 145, the second interlayered insulating layer 155, and the gate spacers 125. Top surfaces of the recess regions RE may be positioned at substantially the same level as those of the gate spacers 125 and the capping pattern 145.

Low-k dielectric layers 143 may be formed to fill the recess regions RE. Accordingly, the low-k dielectric layers 143 may cover opposite sidewalls of the capping pattern 145 and opposite sidewalls 191 of the electrode pattern EP, The low-k dielectric layers 143 may be provided to partially cover the top surface of the work-function metal pattern WF. As shown in FIG. 4A, for example, the low-k dielectric layers 143 may cover opposite sidewalls 192 of the electrode pattern EP in addition to covering opposite sidewalls 191 of the capping pattern 145. The low-k dielectric layers 143 may be provided to at least partially cover inner sidewalls of the gate spacers 125.

A low-k dielectric layer 143 may have a second dielectric constant that is equal to or higher than 1 and is lower than the first dielectric constant. In some example embodiments, the first dielectric constant may be in a range from 4 to 8, and the second dielectric constant may be in a range from 1 to 4. The low-k dielectric layers 143 may include a plurality of low-k dielectric materials. The low-k dielectric materials may constitute a mixture, or may be divided to each other. The low-k dielectric layers 143 may be formed of or include one or more of a gaseous material and a silicon oxide material. In some example embodiments, the low-k dielectric layers 143 may include one or more gaseous materials. Since a dielectric constant of a low-k dielectric layer 143 is lower than a dielectric constant of the capping pattern 145, parasitic capacitance between the gate electrode 135 and the contact CA may be reduced, relative to parasitic capacitance between the gate electrode 135 and the contact CA in a semiconductor device in which the dielectric layers 143 are absent.

As a result, in the gate structure GS according to some example embodiments, the electrode pattern EP may enable reduced resistance of the gate structure GS and the low-k dielectric layers 143, The electrode pattern may enable reduced parasitic capacitance of the gate structure GS. Accordingly AC performance and RC delay property of the semiconductor device may be improved.

As another example, referring to FIGS. 2, 3A, 3B, and 4B, the work-function metal pattern WF may include a first work-function metal pattern WFa and a second work-function metal pattern WFb, which are sequentially stacked on the substrate 100. Here, top surfaces of the first and second work-function metal patterns WFa and WFb may be substantially coplanar with each other. The first and second work-function metal patterns WFa and WFb may include different materials. For example, the first work-function metal pattern WFa may have a first electric resistance, the second work-function metal pattern WFb may have a second electric resistance, and the electrode pattern EP may have a third electric resistance. The second electric resistance may be smaller than the first electric resistance and greater than the third electric resistance. Accordingly, it is possible to reduce electric resistance of the gate electrode 135 and thereby to improve AC performance of the semiconductor device.

Furthermore, since the work-function metal pattern WF has a double-layer structure, the use of the work-function metal pattern WF may make it possible to variously control the work function of the field effect transistor. For example, the gate structure GS of FIG. 4B may be applied to the PMOSFET region PR, and the gate structure GS of FIG. 4A may be applied to the NMOSFET region NR. Accordingly, it is possible to adaptively control the work function for each region.

As other example, referring to FIGS. 2, 3A, 3B, and 4C, the electrode pattern EP may have a fifth width W5. The fifth width W5 may be greater than the fourth width W4 and may be substantially equal to the second width W2.

The electrode pattern EP may include a pair of third extended portions EPE. The third extended portions EPE may extend in the third direction D3 along inner sidewalls of the gate spacers 125. For example, the third extended portions EPE may partially cover the sidewalls of the capping pattern 145. As shown in FIG. 4C, the third extended portions EPE may cover separate lower portions 191b of the capping pattern 145 sidewalls 191, and the low-k dielectric layers 143 may cover separate upper portions 191a of the capping pattern 145 sidewalls 191. The third extended portions EPE may have top surfaces positioned at a higher level than the bottom surface of the capping pattern 145. The recess regions RE may have the bottom surfaces positioned at substantially the same level as the top surfaces of the third extended portions ERE. Accordingly, the top surfaces of the third extended portions EPE may be in direct contact with the low-k dielectric layers 143.

As still other example, referring to FIG. 2, FIG. 3A, FIG. 3B, and FIG. 4D, the electrode pattern EP may have a sixth width W6, and the capping pattern 145 may have a seventh width W7. The sixth width W6 may be smaller than the third width W3 described with reference to FIG. 4A, and the seventh width W7 may be smaller than the fourth width W4 described with reference to FIG. 4A.

As shown in FIG. 4D, a low-k dielectric layer 143 may include a first portion 143a and a second portion 143b. The first portion 143a may be or include gaseous material, and the second portion 143b may be or include a silicon oxide material. In some example embodiments, the low-k dielectric layers 143 may include the gaseous material and the silicon oxide material, which are sequentially stacked. As shown in FIG. 4D, the second portion 143b of a low-k dielectric layer 143 may cover an upper portion 191a of a sidewall 191 of the capping pattern 145. The first portion 143a of the low-k dielectric layer 143 may cover a lower portion 191b of the sidewall 191 of the capping pattern and a sidewall 192 of the electrode pattern EP. In some example embodiments, the second portion 143h may cover a sidewall 191 of the capping pattern 145 and a first portion of a sidewall 192 of the electrode pattern EP, while the first portion 143a may cover a second portion of the sidewall 192 of the electrode pattern EP. The second portion 143b, in conjunction with the second interlayered insulating layer 155, may constitute a single body. In other words, the second portion 143b may also be a portion of the second interlayered insulating layer 155 extended into the recess region RE. This is because, when the sixth and seventh widths W6 and W7 decrease, the widths of the recess regions RE may increase, and in this case, the recess regions RE may be partially tilled with a silicon oxide, during the formation of the second interlayered insulating layer 155. As described above, the second portion 143b, in conjunction with the second interlayered insulating layer 155, may form a single body, but since the second portion 143b is positioned in the recess regions RE, the second portion 143b may be included in one or more of the low-k dielectric layers 143 according to some example embodiments.

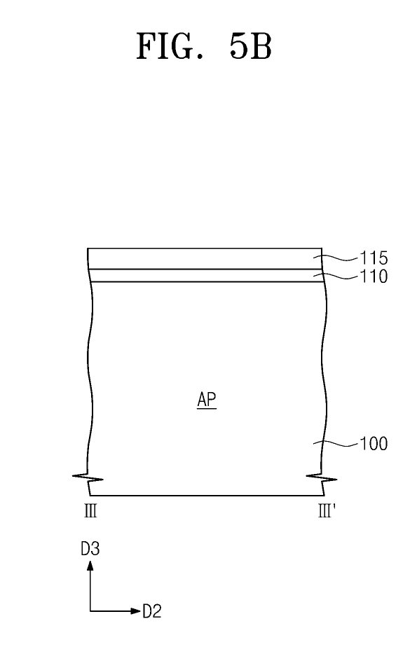

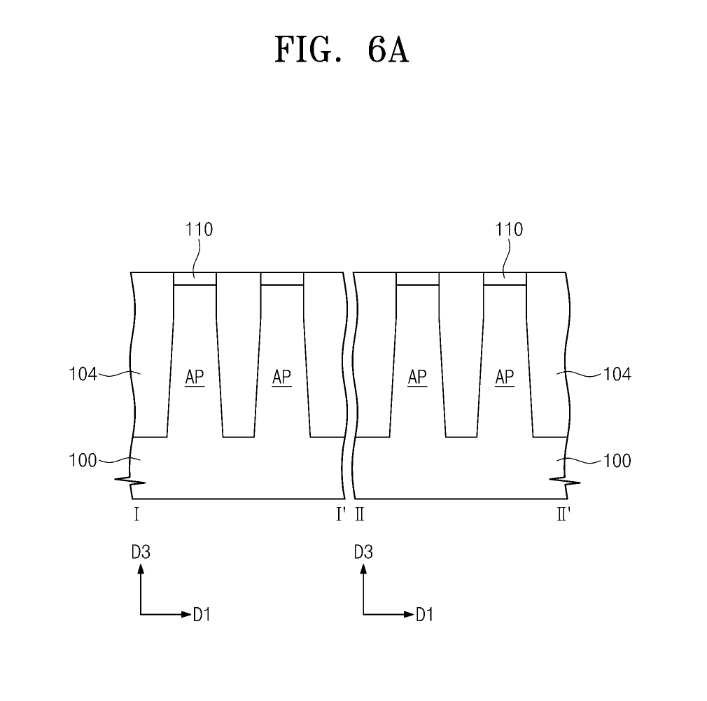

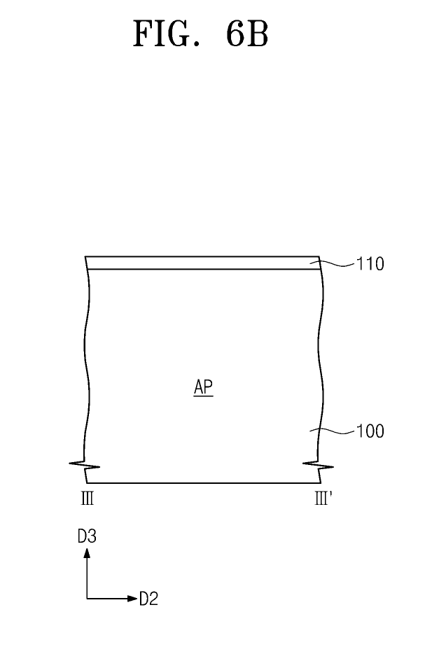

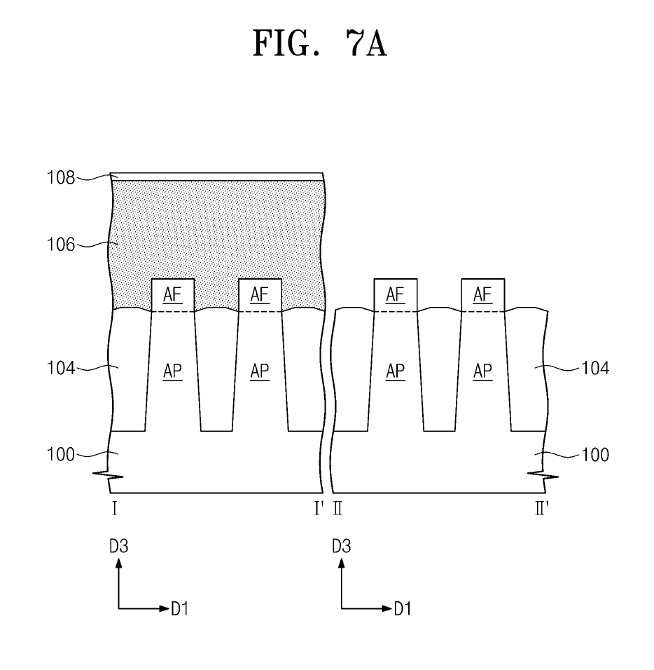

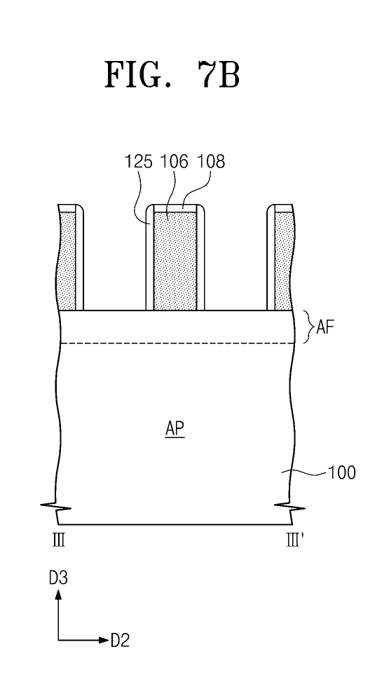

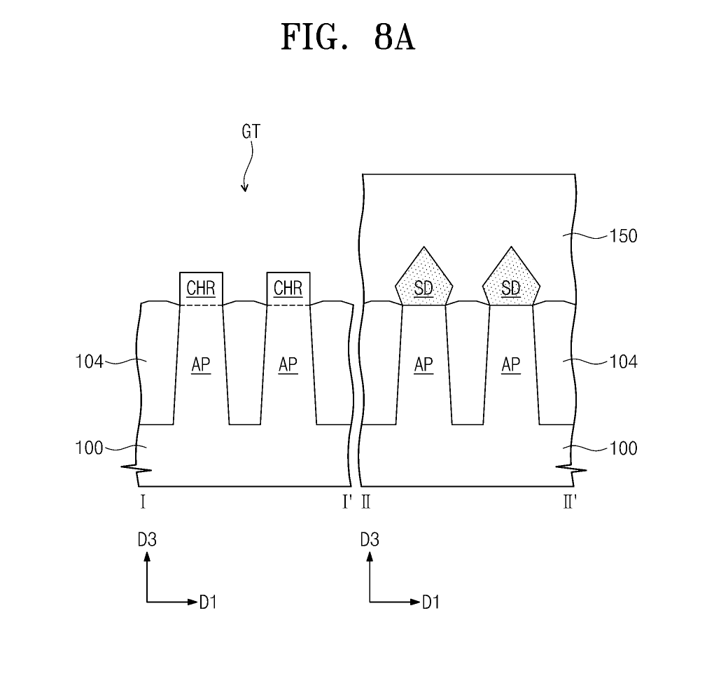

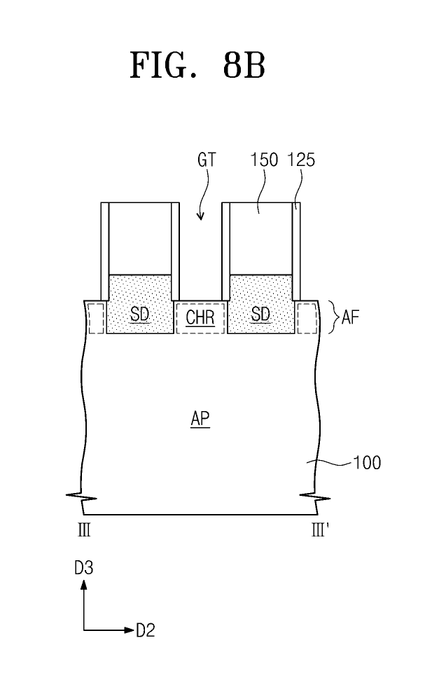

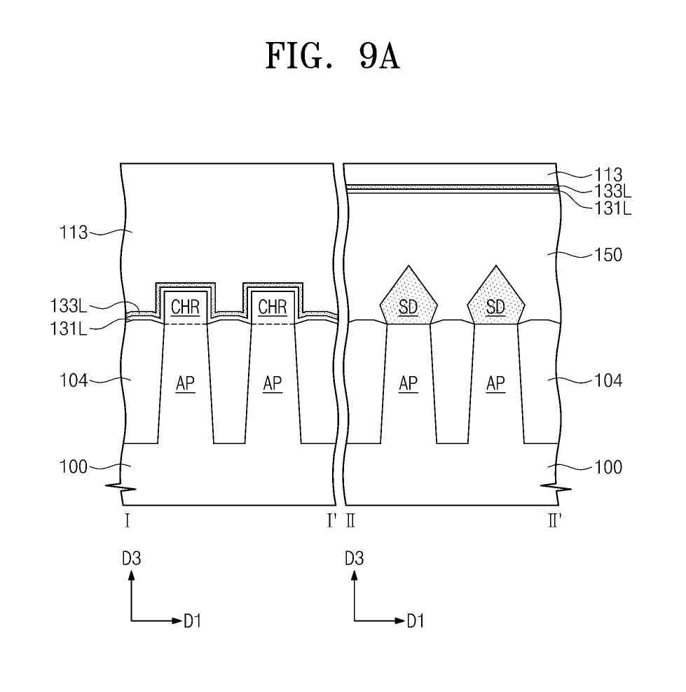

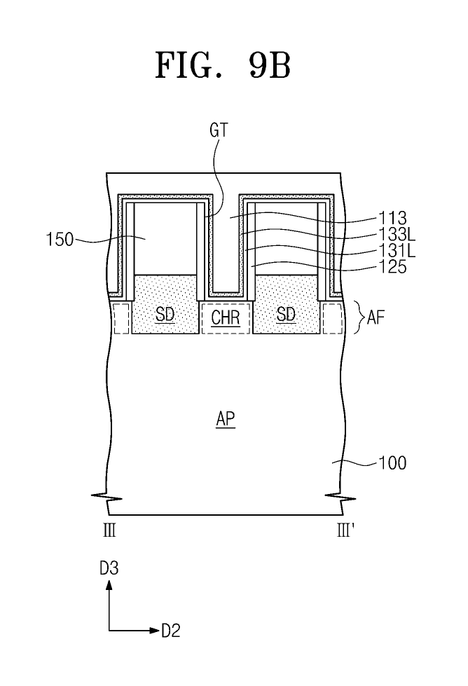

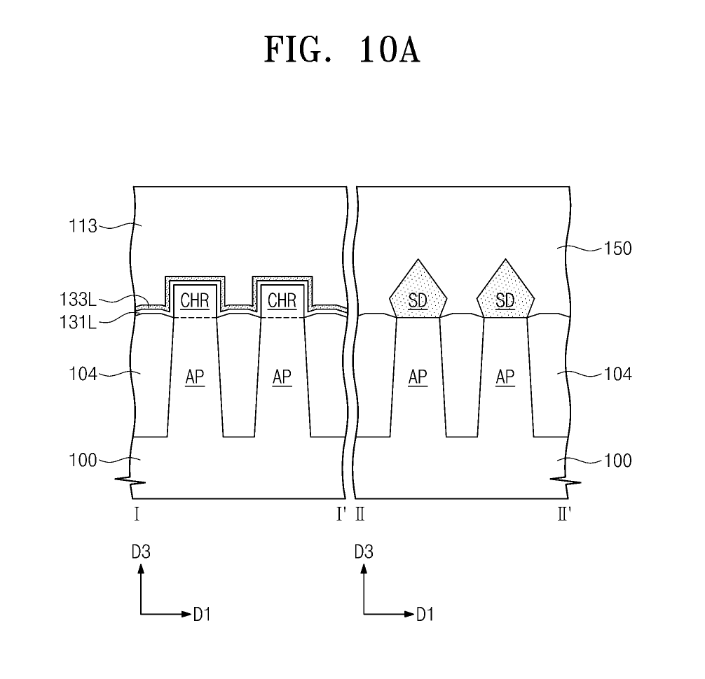

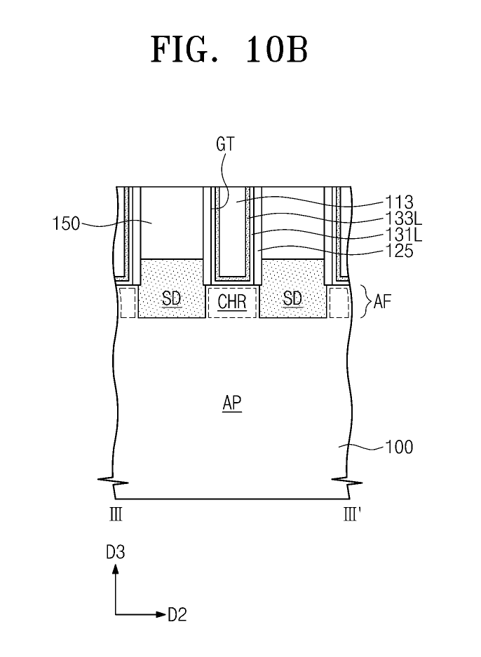

FIG. 5A, FIG. 5B, FIG. 6A, FIG. 6B, FIG. 7A, FIG. 7B, FIG. 8A, FIG. 8B, FIG. 9A, FIG. 9B, FIG. 10A, FIG. 10B, FIG. 11A, FIG. 11B, FIG. 12A, FIG. 12B, FIG. 13A, FIG. 13B, FIG. 14A, and FIG. 14B are sectional views illustrating a method of fabricating a semiconductor device, according to some example embodiments of the inventive concepts. FIG. 5A, FIG. 6A, FIG. 7A, FIG. 8A, FIG. 9A, FIG. 10A, FIG. 11A, FIG. 12A, FIG. 13A, and FIG. 14A are sectional views taken along lines I-I′ and II-II′ of FIG. 2. FIG. 5B, FIG. 6B, FIG. 7B, FIG. 8B, FIG. 9B, FIG. 10B, FIG. 11B, FIG. 12B, FIG. 13B, and FIG. 14B are sectional views taken along line of FIG. 2.

Referring to FIG. 2, FIG. 5A, and FIG. 5B, the substrate 100 may be patterned to form device isolation trenches 105 defining the active patterns AP. The substrate 100 may be a semiconductor substrate (e.g., of silicon, germanium, or silicon-germanium) or a compound semiconductor substrate. The active patterns AP may be doped with dopants to have a first conductivity type.

The formation of the device isolation trenches 105 may include forming mask patterns on the substrate 100 and anisotropically etching the substrate 100 using the mask patterns an etch mask. Each of the mask patterns may include a first mask pattern 110 and a second mask pattern 115, which are sequentially stacked on the substrate 100 and are formed to have an etch selectivity with respect to each other. Each of the device isolation trenches 105 may be formed to have an aspect ratio of at least 5. In some example embodiments, each of the device isolation trenches 105 may be formed to have a downward tapered shape. Accordingly, each of the active patterns AP may be formed to have an upward tapered shape.

Referring to FIG. 2, FIG. 6A, and FIG. 6B, the device isolation layers 104 may be formed to fill the device isolation trenches 105. The formation of the device isolation layers 104 may include forming an insulating layer (e.g., a silicon oxide layer) to fill the device isolation trenches 105 and planarizing the insulating layer to expose the top surface of the first mask pattern 110. As a result of the planarization process, the device isolation layers 104 may be locally formed in the device isolation trenches 105.

Referring to FIG. 2, FIG. 7A. and FIG. 7B, top portions (hereinafter, active fins AF) of the active patterns AP may be exposed. The exposing of the active fins AF may include, for example, recessing top portions of the device isolation layers 104 using a wet etching process. The recessing of the device isolation layers 104 may be performed using an etch recipe having an etch selectivity with respect to the active patterns AP. The recessing of the device isolation layers 104 may be performed to remove the first mask pattern 110 and thereby to expose top surfaces of the active fins AF.

Sacrificial gate patterns 106 and gate mask patterns 108, which are sequentially stacked, may be formed on the active fins AF. Each of the sacrificial gate patterns 106 and the gate mask patterns 108 may be formed to cross the active fins AF or to have a line- or bar-shaped structure extending in the first direction D1. For example, the formation of the sacrificial gate patterns 106 and the gate mask patterns 108 may include sequentially forming a sacrificial gate layer and a gate mask layer on the active fins AF and the device isolation layers 104 and patterning the sacrificial gate layer and the sacrificial mask layer. The sacrificial gate layer may be formed of or include a poly-silicon layer. The gate mask layer may be formed of or include a silicon nitride layer or a silicon oxynitride layer.

The gate spacers 125 may be formed on both sidewalls of each of the sacrificial gate patterns 106. The formation of the gate spacers 125 may include conformally forming a spacer layer on the resulting structure provided with the sacrificial gate pattern 106 and anisotropically etching the spacer layer. The spacer layer may be formed of or include at least one of SiO2, SiCN, SiCON, and SiN. Alternatively, the spacer layer may be formed to have a multi-layer structure including at least one of SiO2, SiCN, SiCON, or SiN.

Referring to FIG. 2, FIG. 8A, and FIG. 8B, the source/drains SD may be formed at both sides of each of the sacrificial gate patterns 106. For example, the source/drains SD may be formed by a selective epitaxial growth process using the substrate 100 as a seed layer. The selective epitaxial growth process may include a chemical vapor deposition (CVD) process or a molecular beam epitaxy (MBE) process. In detail, the active fins AF may be selectively etched using the gate mask patterns 108 and the gate spacers 125 as an etch mask. After the etching of the active fins AF, an epitaxial process, in which the exposed top portions of the active patterns AP are used as a seed layer, may be performed to form the source/drains SD. As a result of the formation of the source/drains SD, the channel regions CFR may be defined between the source/drains SD.

The top surfaces of the source/drains SD may be positioned at a higher level than those of the channel regions CHR. In addition, the top surfaces of the source/drains SD may have a non-vanishing curvature. For example, the top surface of each of the source/drains SD may have an upwardly convex profile.

The source/drains SD may include a semiconductor element different from those of the substrate 100. For example, the source/drains SD may be formed of or include a semiconductor material having a lattice constant different from (for example, greater or smaller than) the substrate 100. This may make it possible to exert a compressive stress or a tensile stress to the channel regions CHR. In the case where the substrate 100 is a silicon wafer, the source/drains SD may be formed of or include a silicon-germanium (e.g., e-SiGe) or germanium layer. In this case, the source/drains SD may exert a compressive stress on the channel regions CHR (preferably, of PMOS field effect transistors). In the case where the substrate 100 is a silicon wafer, the source/drains SD may be formed of or include a silicon carbide (SiC) layer. In this case, the source/drains SD may exert a tensile stress on the channel regions CHR (preferably, of NMOS field effect transistors). The compressive or tensile stress to be exerted on the channel regions CHR by the source/drains SD may make it possible for carriers in the channel regions CHR to have an increased mobility, when the field effect transistors according to some example embodiments of the inventive concepts are operated.

The source/drains SD may be doped to have a second conductivity type that is different from the first conductivity type of the active patterns AP. As an example, dopants may be injected in an in-situ manner to realize the second conductivity type of the source/drains SD. As another example, an ion implantation process may be performed to realize the second conductivity type of the source/drains SD, after the formation of the source/drains SD.

Next, the first interlayered insulating layer 150 may be formed to cover the source/drains SD. For example, the formation of the first interlayered insulating layer 150 may include forming an insulating layer on the substrate 100 to cover the sacrificial gate patterns 106 and the gate mask patterns 108. The first interlayered insulating layer 150 may include a silicon oxide layer, which may be formed by a flowable chemical vapor deposition (FCVD) process.

Thereafter, the first interlayered insulating layer 150 may be planarized to expose the top surfaces of the sacrificial gate patterns 106. The planarization of the first interlayered insulating layer 150 may be performed using an etch-back process or a chemical-mechanical polishing (CMP) process. The planarization of the first interlayered insulating layer 150 may be performed to remove the gate mask patterns 108 and thereby to expose the top surfaces of the sacrificial gate patterns 106. Also, the planarization of the first interlayered insulating layer 150 may be performed to remove upper portions of the gate spacers 125. As a result, the first interlayered insulating layer 150 may have a top surface substantially coplanar with those of the sacrificial gate patterns 106 and the gate spacers 125.

The sacrificial gate patterns 106 may be removed to form gate trenches GT. The gate trenches GT may be formed by an etching process of selectively removing the sacrificial gate patterns 106. The channel regions CHR of the active fins AF may be exposed by the gate trenches GT.

Referring to FIG. 2, FIG. 9A, and FIG. 9B, a gate dielectric layer 131L, a barrier layer 133L, and a dummy filler layer 113 may be sequentially formed to fill the gate trenches GT. The gate dielectric layer 131L and the barrier layer 133L may be conformally formed to partially, but not completely, fill the gate trenches GT.

The gate dielectric layer 131L may be formed by an atomic layer deposition (ALD) process or a chemical oxidation process. The gate dielectric layer 131L may be formed of or include a high-k dielectric material. For example, the gate dielectric layer 131L may be formed of or include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The barrier layer 133L may be formed by an atomic layer deposition (ALD) process or a chemical vapor deposition (CVD) process. As an example, the barrier layer 133L may include binary metal nitrides (e.g., titanium nitride (TiN), tantalum nitride (TaN), tungsten nitride (WN), and hafnium nitride (HfN)) and/or ternary metal nitrides (e.g., titanium aluminum nitride (TiAlN), tantalum aluminum nitride (TaAlN), and hafnium aluminum nitride (HfAlN)). The barrier layer 133L may include a plurality of different metal layers (e.g., see FIG. 4A, FIG. 4B, FIG. 4C, and FIG. 4D), but example embodiments of the inventive concepts may not be limited thereto.

The dummy filler layer 113 may be formed to completely fill the remaining portions of the gate trenches GT. In some example embodiments, the dummy filler layer 113 may include a carbon-containing organic compound. Here, the dummy filler layer 113 may be formed on the entire top surface of the substrate 100 and by a spin coating process. In some example embodiments, the dummy filler layer 113 may include a silicon oxide layer or a poly-silicon layer. In the case where the dummy filler layer 113 includes a silicon oxide layer or a poly-silicon layer, the dummy filler layer 113 may be formed by a chemical vapor deposition (CVD) process.

Referring to FIG. 2, FIG. 10A, and FIG. 10B, a planarization process may be performed on the gate dielectric layer 131L, the barrier layer 133L, and the dummy filler layer 113 to expose the first interlayered insulating layer 150. The planarization process may be performed using an etch-back or chemical-mechanical polishing (CMP) process. As a result, the gate dielectric layer 131L, the barrier layer 133L, and the dummy filler layer 113 may be localized within the gate trenches GT.

Referring to FIG. 2, FIG. 11A, and FIG. 11B, upper portions of the gate dielectric layer 131L and the barrier layer 133L may be removed from regions between the gate spacers 125 and the dummy filler layer 113. For example, the upper portions of the gate dielectric layer 131L and the barrier layer 133L may be etched using the gate spacers 125 and the dummy filler layer 113 as an etch mask to form the gate dielectric pattern 131 and the barrier pattern 133.

The gate dielectric pattern 131 may include the first extended portions 125E interposed between the gate spacers 125 and the dummy filler layer 113, and the barrier pattern 133 may include the second extended portions 133E interposed between the gate spacers 125 and the dummy filler layer 113 (e.g., see FIG. 4A). The first and second extended portions 125E and 133E may have top surfaces that are substantially coplanar with each other and are positioned between top and bottom surfaces of the dummy filler layer 113.

Referring to FIG. 2, FIG. 12A, and FIG. 12B, the dummy filler layer 113 may be removed and the work-function metal patterns WF may be formed on the gate dielectric pattern 131 and the barrier pattern 133 to fill the gate trenches GT. For example, the formation of the work-function metal patterns WF may include forming a work-function metal layer on the gate dielectric pattern 131 and the barrier pattern 133 to fill the gate trenches GT and then planarizing the work-function metal layer to expose the top surface of the first interlayered insulating layer 150. Thereafter, the planarized upper portion of the work-function metal layer may be selectively removed by an etching process. As a result, the work-function metal pattern WF may be locally formed in each of the gate trenches GT. The work-function metal pattern WF may have a top surface lower than that of the first interlayered insulating layer 150. The work-function metal pattern WF may be a line-shaped structure extending parallel to the first direction D1. The work-function metal layer may be formed by a deposition process (e.g., a sputtering or CVD process).

The work-function metal layer may be formed of or include at least one of metals (e.g., titanium (Ti), tantalum (Ta), hafnium (Hf), tungsten (W), molybdenum (Mo), or aluminum (Al)), nitrides containing at least one of the metals, carbides, silicon nitride, or suicides. In some example embodiments, the work-function metal pattern WF may be formed of or include platinum (pt), rubidium (Ru), iridium oxide (IrO), or rubidium oxide (RuO). The work-function metal layer may include a plurality of metal layers, whose work functions are different from each other (e.g., see FIG. 4B), but example embodiments of the inventive concepts may not be limited thereto.

Referring to FIG. 2, FIG. 13A, and FIG. 13B, the electrode patterns EP and the capping patterns 145 may be formed on the work-function metal patterns WF to fill the gate trenches GT, respectively. The work-function metal pattern WF and the electrode pattern EP provided in each of the gate trenches GT may constitute the gate electrode 135. In detail, an electrode metal layer may be formed on the work-function metal patterns WF to partially fill the gate trench GT, and a capping layer may be formed on the electrode metal layer to fill the remaining region of the gate trench GT. Thereafter, the electrode metal layer and the capping layer may be planarized to expose the top surface of the first interlayered insulating layer 150 and thereby to form the electrode patterns EP and the capping patterns 145.

The electrode metal layer may be formed by a deposition process, such as an atomic layer deposition (ALD) process, a chemical vapor deposition (CVD) process, or a sputtering process. The electrode metal layer may be formed of or include at least one low resistance metallic material, such as aluminum (Al), tungsten (W), titanium (Ti), or tantalum (Ta).

The capping layer may be formed by an atomic layer deposition (ALB) process, a plasma-enhanced chemical vapor deposition (PECVD) process, or a high-density plasma chemical vapor deposition (HDPCVD) process. The capping layer may be formed of a material having an etch selectivity with respect to the first and second interlayered insulating layers 150 and 155. For example, the capping layer may be formed of or include at least one of SiON, SiCN, SiCON, or SiN.

Referring to FIG. 2, FIG. 14A, and FIG. 14B, the electrode patterns EP may be etched using the capping patterns 145 as an etch mask, and thus, the recess regions RE may be formed to expose the sidewalls 191 of the capping patterns 145. In detail, the etching of the electrode patterns EP may be performed by a wet or dry etching process using the etch selectivity of the electrode patterns EP with respect to the capping patterns 145, the gate spacers 125, and the first interlayered insulating layer 150. Accordingly, sidewall portions of the electrode patterns EP interposed between the capping patterns 145 and the gate spacers 125 may be removed to expose sidewalls 192 of the electrode patterns EP and to form the recess regions RE between the capping patterns 145 and the gate spacers 125. Each of the recess regions RE may be an empty space that is delimited or defined by the work-function metal pattern WF, the electrode pattern EP, the capping pattern 145, and the gate spacer 125.

The low-k dielectric layers 143 may be formed to fill the recess regions RE. In the present embodiment, the low-k dielectric layers 143 may be gaseous material or air. The gate spacers 125, the gate dielectric pattern 131, the barrier pattern 133, the gate electrode 135, the capping pattern 145, and the low-k dielectric layers 143 may comprise the gate structure GS.

Referring to FIG. 2, FIG. 3A, and FIG. 3B, the second interlayered insulating layer 155 may be formed on the first interlayered insulating layer 150 and the gate structures GS. The second interlayered insulating layer 155 may be formed of or include a silicon oxide layer or a low-k oxide layer. The low-k oxide layer may include, for example, a carbon-doped silicon oxide layer (e.g., SiCOH). The second interlayered insulating layer 155 may be formed by a CVD process.

Thereafter, contact holes may be formed to penetrate the second interlayered insulating layer 155 and the first interlayered insulating layer 150 and expose the source/drains SD. As an example, the contact holes may be formed in a self-aligned manner by the capping patterns 145 and the gate spacers 125.

Although not shown, metal silicide layers may be formed on the source/drains SD exposed by the contact holes. The metal silicide layers may include at least one of, for example, titanium silicide, tantalum silicide, or tungsten silicide.

Next, the contacts CA may be respectively formed in the con act holes to be in contact with the metal silicide layers. Each of the contacts CA may include a conductive pillar CP and a contact barrier layer BL enclosing the conductive pillar CP. In detail, the contact barrier layer BL may be formed to partially fill the contact holes. Thereafter, a conductive layer may be formed to completely fill the contact holes, and a planarization process may be performed to expose the top surface of the second interlayered insulating layer 155. The contact barrier layer BL may include a metal nitride layer (e.g., Ti/TiN), and the conductive layer may include a metallic material (e.g., tungsten).

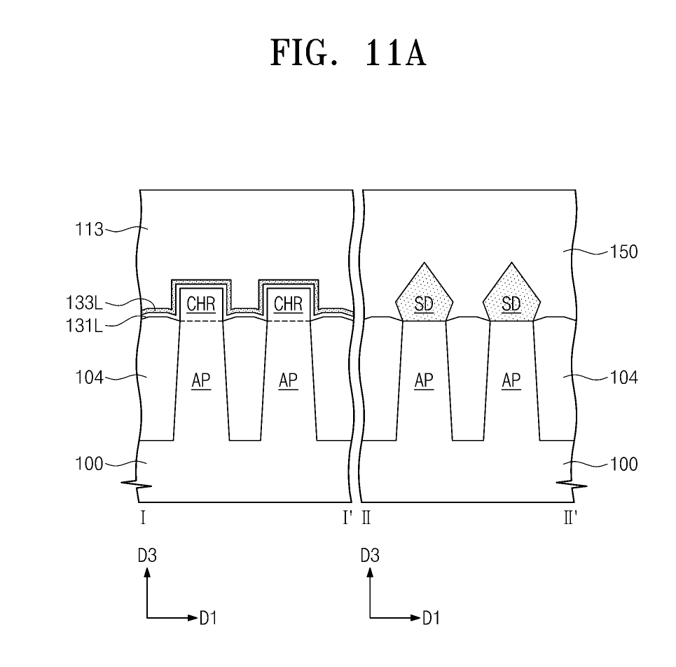

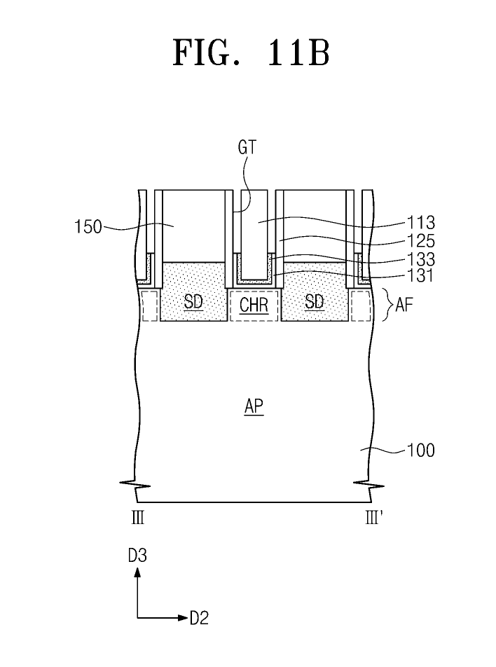

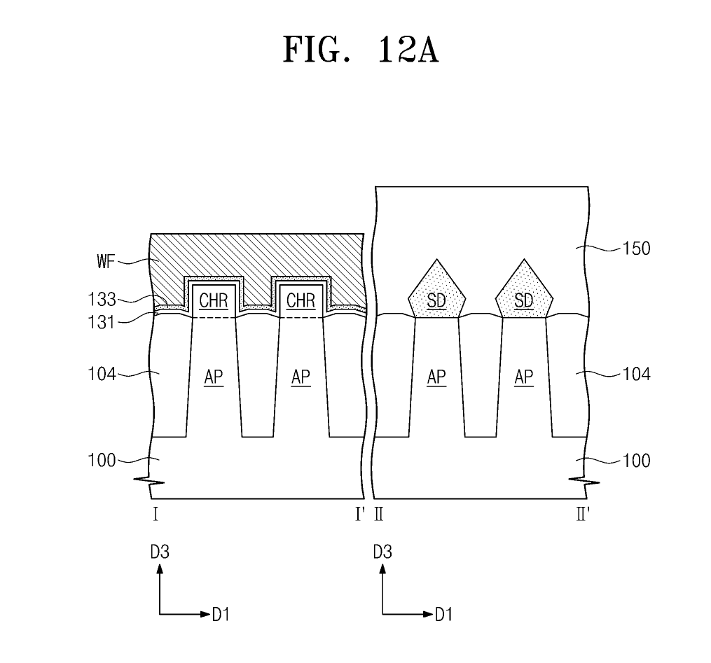

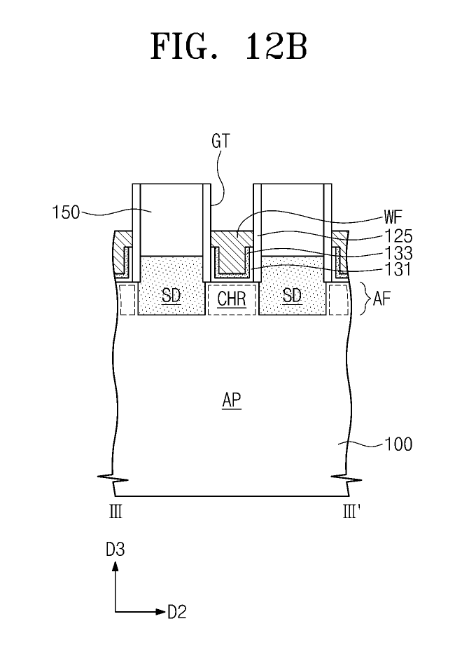

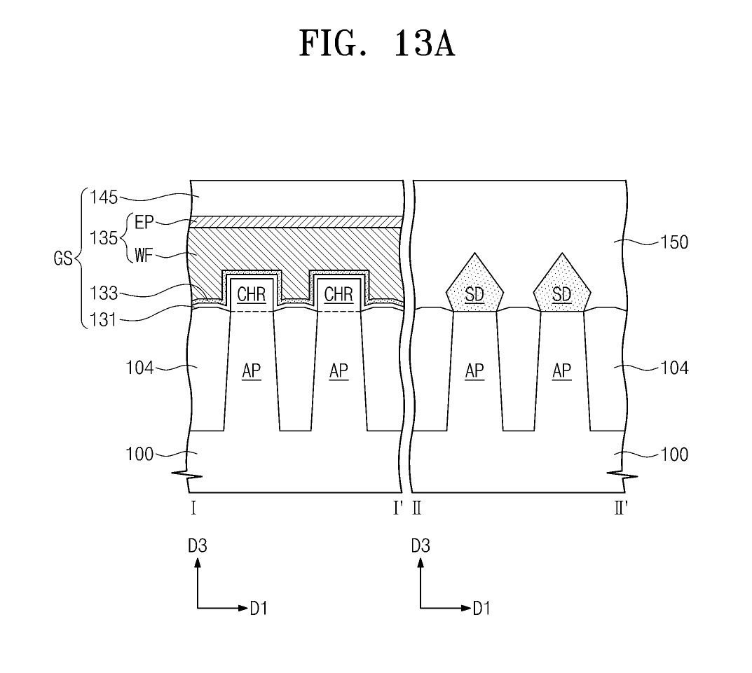

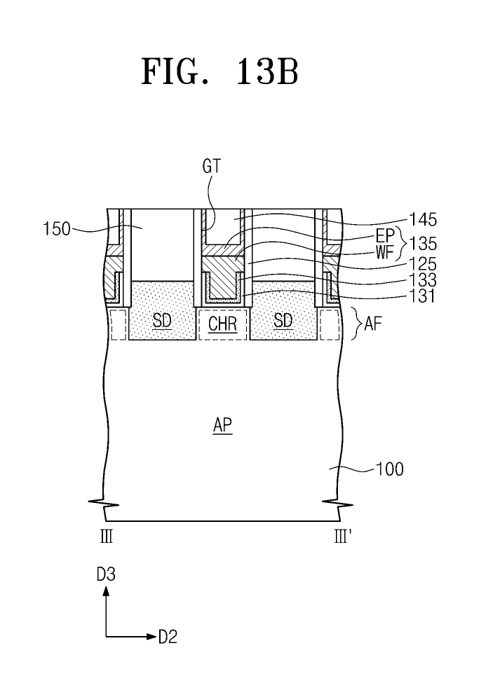

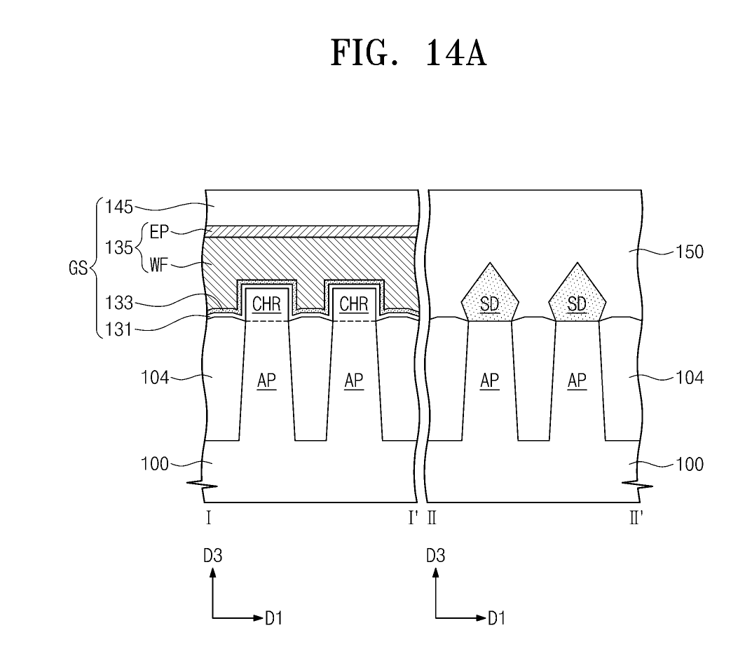

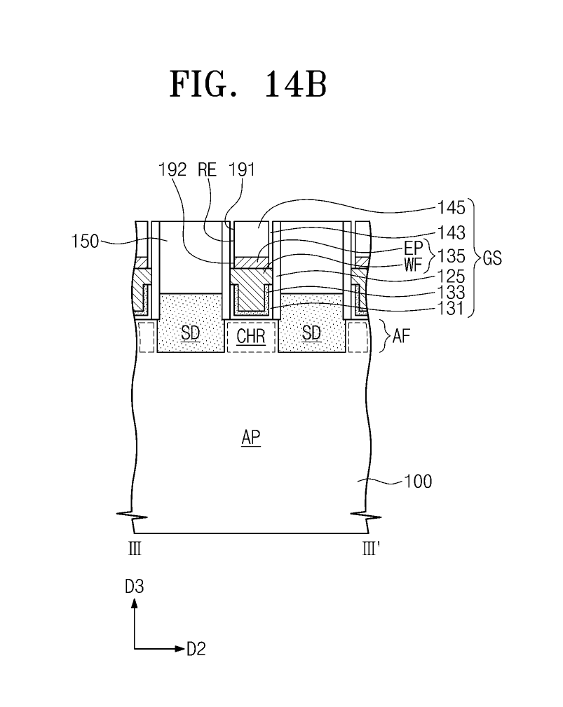

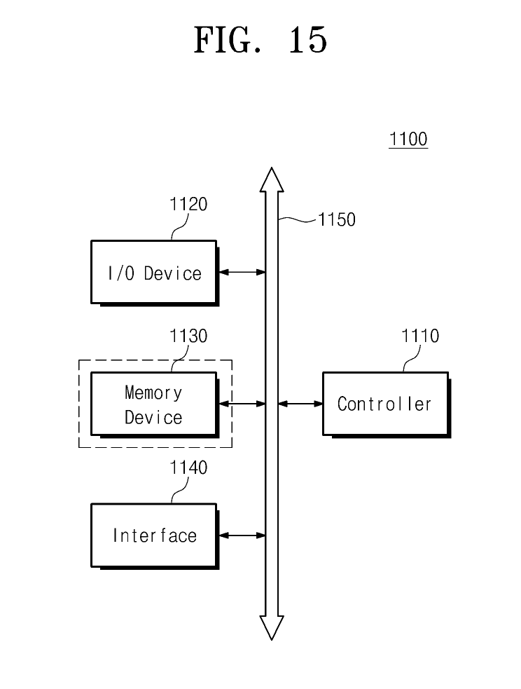

FIG. 15 is a block diagram illustrating an example of an electronic system including a semiconductor device according to some example embodiments of the inventive concepts.

Referring to FIG. 15, an electronic system 1100 according to some example embodiments of the inventive concepts may include a controller 1110, an input-output (I/O) unit 1120, a memory device 1130, an interface unit 1140, and a data bus 1150. At least two of the controller 1110, the I/O unit 1120, the memory device 1130 and the interface unit 1140 may communicate with each other through the data bus 1150. The data bus 1150 may correspond to a path through which electrical signals are transmitted.

The controller 1110 may include at least one of a microprocessor, a digital signal processor, a microcontroller, or another logic device, which is configured to have a similar function to them. The I/O unit 1120 may include a keypad, a keyboard, or a display unit. The memory device 1130 may store data and/or commands. The memory device 1130 may include a nonvolatile memory device (e.g., a FLASH memory device, a phase-change memory device, a magnetic memory device, and so forth). Furthermore, the memory device 1130 may further include a volatile memory device. For example, the memory device 1130 may include a static random access memory (SRAM) device with the semiconductor device according to some example embodiments of the inventive concepts. It may be possible to omit the memory device 1130, depending on the purpose of the electronic system 1100 or a type of an electronic product, for which the electronic system 1100 is used. The interface unit 1140 may transmit electrical data to a communication network or may receive electrical data from a communication network. The interface unit 1140 may operate in a wireless or wired manner. For example, the interface unit 1140 may include an antenna for the wireless communication or a transceiver for the wired and/or wireless communication. A semiconductor device according to some example embodiments of the inventive concepts may be provided as a part of the controller 1110 or the I/O unit 1120. Although not shown in the drawings, the electronic system 1100 may further include a fast DRAM device and/or a fast SRAM device that acts as a cache memory for improving an operation of the controller 1110.

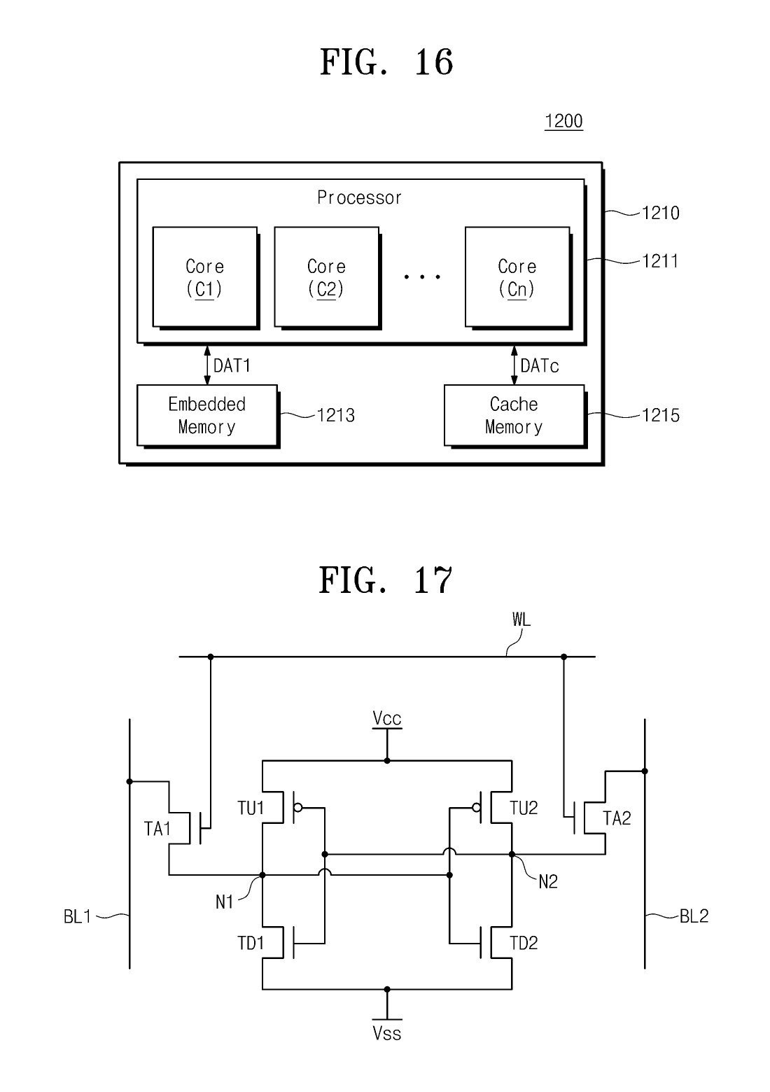

FIG. 16 is a block diagram illustrating an example of an electronic device including a semiconductor device according to some example embodiments of the inventive concepts.

Referring to FIG. 16, an electronic device 1200 may include a semiconductor chip 1210. The semiconductor chip 1210 may include a processor 1211, an embedded memory 1213, and a cache memory 1215.

The processor 1211 may include one or more processor cores C1-Cn. The one or more processor cores C1-Cn may be configured to process data and signals. The processor cores C1-Cn may be configured to include the semiconductor device according to some example embodiments of the inventive concepts (for example, the plurality of logic cells described with reference to FIG. 1).

The electronic device 1200 may be configured to perform its own functions using the processed data and signals. As an example, the processor 1211 may be an application processor.

The embedded memory 1213 may exchange a first data DAT1 with the processor 1211. The first data DAT1 may be data processed, or to be processed, by the one or more processor cores C1-Cn. The embedded memory 1213 may manage the first data DAT1. For example, the embedded memory 1213 may be used for a buffering operation on first data DAT1. In other words, the embedded memory 1213 may be operated as a buffer memory or a working memory for the processor 1211.

In some example embodiments, the electronic device 1200 may be used to realize a wearable electronic device. In general, the wearable electronic device may be configured to perform an operation of calculating a small amount of data, rather than calculating a large amount of data. In this sense, in the case where the electronic device 1200 is used for a wearable electronic device, the embedded memory 1213 may be configured to have a relatively small buffer capacity.

The embedded memory 1213 may be a static random access memory (SRAM) device. The SRAM device may have a faster operating speed than that of a dynamic random access memory (DRAM) device. Accordingly, in the case where the SRAM is embedded in the semiconductor chip 1210, it is possible for the electronic device 1200 to have a small size and a fast operating speed. Furthermore, in the case where the SRAM is embedded in the semiconductor chip 1210, it is possible to reduce an active power of the electronic device 1200. As an example, the SRAM may include at least one of the semiconductor devices according to some example embodiments of the inventive concepts.

The cache memory 1215 may be mounted on the semiconductor chip 1210, along with the one or more processor cores C1-Cn. The cache memory 1215 may be configured to store cache data DATc that will be used or directly accessed by the one or more processor cores C1-Cn, The cache memory 1215 may he configured to have a relatively small capacity and a very fast operating speed. In some example embodiments, the cache memory 1215 may include an SRAM device including the semiconductor device according to some example embodiments of the inventive concepts, in the case where the cache memory 1215 is used, it is possible to reduce an access frequency or an access time to the embedded memory 1213 performed b the processor 1211. In other words, the use of the cache memory 1215 may allow the electronic device 1200 to have a fast operating speed.

To provide better understanding of example embodiments of the inventive concepts, the cache memory 1215 is illustrated in FIG. 16 to be a component separated from the processor 1211. However, the cache memory 1215 may be configured to be included in the processor 1211. In addition, example embodiments of the inventive concepts are not limited to the example illustrated by FIG. 16.

The processor 1211, the embedded memory 1213, and the cache memory 1215 may be configured to exchange or transmit data, based on at least one of various interface protocols. For example, the processor 1211, the embedded memory 1213, and the cache memory 1215 may be figured to exchange or transmit data, based on at least one of Universal Serial Bus (USB), Small Computer System Interface (SCSI), Peripheral Component Interconnect (PCI) Express, Advanced Technology Attachment (ATA), Parallel ATA (RATA), Serial ATA (SATA), Serial Attached SCSI (SAS), integrated Drive Electronics (IDE), or Universal Flash Storage (UFS).

FIG. 17 is an equivalent circuit diagram illustrating an SRAM cell according to some example embodiments of the inventive concepts. The SRAM cell may be realized by at least one of the semiconductor devices according to some example embodiments of the inventive concepts. The SRAM cell may be used for the embedded memory 1213 and/or the cache memory 1215 of FIG. 16.

Referring to FIG. 17, the SRAM cell may include a first pull-up transistor TU1, a first pull-down transistor TD1, a second pull-up transistor TU2, a second pull-down transistor TD2, a first access transistor TA1, and a second access transistor TA2. The first and second pull-up transistors TU1 and TU2 may be PMOS transistors, whereas the first and second pull-down transistors TD1 and TD2 and the first and second access transistors TA1 and TA2 may be NMOS transistors.

A first source/drain of the first pull-up transistor TU1 and a first source/drain of the first pull-down transistor TD1 may be connected to a first node N1. A second source/drain of the first pull-up transistor TU1 may be connected to a power line Vcc, and a second source/drain of the first pull-down transistor TD1 may be connected to a ground line Vss. A gate of the first pull-up transistor TU1 and a gate of the first pull-down transistor TD1 may be electrically connected to each other. Accordingly, the first pull-up transistor TU1 and the first pull-down transistor TD1 may constitute a first inverter. The mutually-connected gates of the first pull-up transistor TU1 and the first pull-down transistor TD1 may serve as an input terminal of the first inverter, and the first node N1 may serve as an output terminal of the first inverter.

A first source/drain of the second pull-up transistor TU2 and a first source/drain of the second pull-down transistor TD2 may be connected to the second node N2. A second source/drain of the second pull-up transistor TU2 may be connected to the power line Vcc, and a second source/drain of the second pull-down transistor TD2 may be connected to the ground line Vss. A gate of the second pull-up transistor TU2 and a gate of the second pull-down transistor TD2 may be electrically connected to each other. Accordingly, the second pull-up transistor TU2 and the second pull-down transistor TD2 may constitute a second inverter. The mutually-connected gates of the second pull-up transistor TU2 and the second pull-down transistor TD2 may serve as an input terminal of the second inverter, the second node N2 may serve as an output terminal of the second inverter.

The first and second inverters may be coupled with each other to form a latch structure. In other words, the gates of the first pull-up transistor TU1 and the first pull-down transistor TD1 may be electrically connected to the second node N2, and the gates of the second pull-up and second pull-down transistors TU2 and TD2 may be electrically connected to the first node N1. The first source/drain of the first access transistor TA1 may be connected to the first node N1, and the second source/drain of the first access transistor TA1 may be connected to a first bit line BL1. The first source/drain of the second access transistor TA2 may be connected to the second node N2, and the second source/drain of the second access transistor TA2 may be connected to a second bit line BL2. The gates of the first and second access transistors TA1 and TA2 may be electrically coupled to a word line WL. The SRAM cell according to some example embodiments of the inventive concepts may have the afore-described structure, but example embodiments of the inventive concepts are not limited thereto.

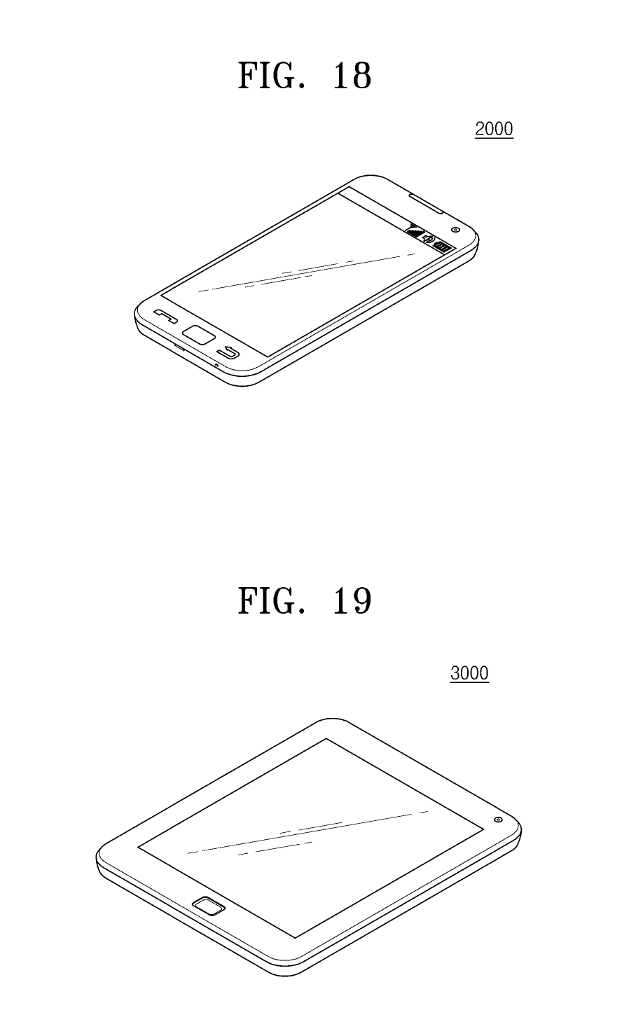

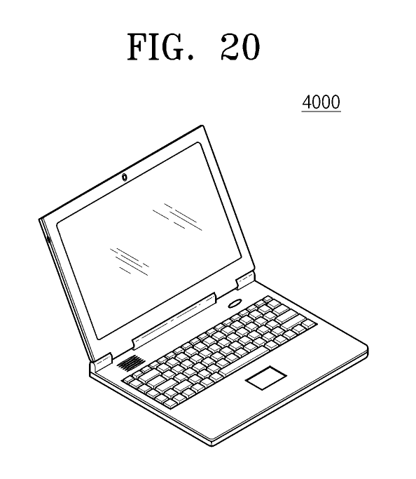

FIG. 18, FIG. 19, and FIG. 20 are diagrams illustrating some examples of a multimedia device including a semiconductor device according to some example embodiments of the inventive concepts. The electronic system 1100 of FIG. 15 and/or the electronic device 1200 of FIG. 16 may be applied to a mobile or smart phone 2000 shown in FIG. 18, to a tablet or smart tablet PC 3000 shown in FIG. 19, or to a laptop computer 4000 shown in FIG. 20.

According to some example embodiments of the inventive concepts, it is possible to reduce gate resistance and parasitic capacitance of a semiconductor device and thereby to improve electrical characteristics (e.g., AC performance and RC delay) of the semiconductor device. It is possible to simplify a process of fabricating the semiconductor device, without an additional step.

While example embodiments of the inventive concepts have been particularly shown and described, it will be understood by one of ordinary skill in the art that variations in form and detail may be made therein without departing from the spirit and scope of the attached claims.

1. A semiconductor device, comprising:
a substrate including an active pattern; and
a gate structure crossing the active pattern, the gate structure including,
a gate electrode;
a capping pattern on the gate electrode, the capping pattern having a first dielectric constant;
spacers extending in parallel with opposite sidewalls of the gate electrode; and
low-k dielectric layers, each of the low-k dielectric layers being between separate, respective sidewalls of the capping pattern and separate, respective spacers of the spacers, the low-k dielectric layers having a second dielectric constant, a bottom surface of each of the low-k dielectric layers being at a higher level than a bottom surface of the gate electrode, and the second dielectric constant being greater than or equal to 1 and being smaller than the first dielectric constant.

2. The device of claim 1, further comprising:
an interlayered insulating layer covering the gate structure, wherein each of the low-k dielectric layers is enclosed by the interlayered insulating layer, a separate spacer of the spacers, the capping pattern, and the gate electrode.

3. The device of claim 1, wherein each of the low-k dielectric layers is in direct contact with the capping pattern and a separate spacer of the spacers.

4. The device of claim 1, wherein the capping pattern, the spacers, and the low-k dielectric layers have coplanar top surfaces.

5. The device of claim 1, wherein
the gate structure further includes a gate dielectric pattern between the substrate and the gate electrode,
the gate dielectric pattern includes a first extended portion extending in a direction perpendicular to a top surface of the substrate, and
the gate electrode covers a top surface of the first extended portion.

6. The device of claim 1, wherein
the gate structure further includes a barrier pattern between the substrate and the gate electrode, the barrier pattern including a second extended portion extending in a direction perpendicular to a top surface of the substrate, and
the gate electrode covers a top surface of the second extended portion.

7. The device of claim 6, wherein
the barrier pattern includes a first barrier layer and a second barrier layer, the first and second barrier layers being sequentially stacked on the substrate, and
the first and second barrier layers include different materials.

8. The device of claim 1, wherein
the gate electrode includes an upper portion and a lower portion, and
a width of the upper portion of the gate electrode is greater than a width of the lower portion of the gate electrode.

9. The device of claim 1, wherein
the gate electrode includes a first work-function metal pattern,
the gate electrode includes an electrode pattern on an upper portion of the first work-function metal pattern, and
a width of the electrode pattern is smaller than a width of the upper portion of the first work-function metal pattern.

10. The device of claim 9, wherein
the low-k dielectric layers cover opposite sidewalls of the electrode pattern, and
the low-k dielectric layers cover a portion of a top surface of the first work-function metal pattern.

11. The device of claim 9, wherein the width of the electrode pattern is substantially equal to a width of the capping pattern.

12-15. (canceled)

16. The device of claim 1, wherein the low-k dielectric layer includes at least one of a gaseous material and a silicon oxide material.

17. (canceled)

18. A semiconductor device, comprising:
a substrate including an active pattern; and
a gate structure crossing the active pattern, the gate structure including,
a gate electrode, the gate electrode having a first width;
a capping pattern on the gate electrode, the capping pattern having a second width that is smaller than the first width of the gate electrode; and
low-k dielectric layers covering opposite sidewalls of the capping pattern, the low-k dielectric layers having a dielectric constant ranging from 1 to 4.

19. The device of claim 18, wherein
the gate electrode includes a work-function metal pattern,
the gate electrode includes an electrode pattern on the work-function metal pattern, and
a width of an upper portion of the work-function metal pattern is greater than a width of a lower portion of the work-function metal pattern.

20. The device of claim 19, wherein the low-k dielectric layers cover opposite sidewalls of the electrode pattern.

21-29. (canceled)

30. A semiconductor device, comprising:
a substrate including an active pattern; and
a gate structure crossing the active pattern, the gate structure including,
a gate electrode;
a capping pattern on the gate electrode, the capping pattern having a first dielectric constant; and
a low-k dielectric layer at least partially covering a sidewall of the capping pattern, the low-k dielectric layer having a second dielectric constant, the second dielectric constant being smaller than the first dielectric constant.

31. The semiconductor device of claim 30, wherein
the gate electrode includes an extended portion, the extended portion covering a lower portion of the sidewall of the capping pattern.

32. The semiconductor device of claim 30, wherein
the low-k dielectric layer includes a first portion and a second portion, and
the first and second portions include different materials.

33. The semiconductor device of claim 32, wherein
the first portion covers an upper portion of the sidewall, and
the second portion covers a lower portion of the sidewall.

34. The semiconductor device of claim 33, further comprising:
an interlayered insulating layer covering the gate structure, wherein the first portion of the low-k dielectric layer is an extended portion of the interlayered insulating layer.
